(19) United States
(12) Patent Application Publication
(10) Pub. No.: US 2010/0195762 A1
(43) Pub. Date: Aug. 5, 2010

(54) DIGITAL BROADCASTING SYSTEM AND METHOD OF PROCESSING DATA IN DIGITAL BROADCASTING SYSTEM

(76) Inventors: In Hwan Choi, Gyeonggi-do (KR); Chul Soo Lee, Seoul (KR); Min Sung Kwak, Seoul (KR); Jae Hyung Song, Seoul (KR)

Correspondence Address: LEE, HONG, DEGERMAN, KANG & WAIMEY, 660 S. FIGUEROA STREET, Suite 2300, LOS ANGELES, CA, 90017, US

(21) Appl. No.: 12/756,992

(22) Filed: Apr. 8, 2010

Related U.S. Application Data
(63) Continuation of application No. 12/235,568, filed on Sep. 22, 2008, now Pat. No. 7,733,820.
(60) Provisional application No. 60/974,084, filed on Sep. 21, 2007.
(60) Provisional application No. 60/977,379, filed on Oct. 4, 2007.
(60) Provisional application No. 61/044,504, filed on Apr. 13, 2008.
(60) Provisional application No. 61/076,686, filed on Jun. 29, 2008.

(30) Foreign Application Priority Data
Sep. 19, 2008 (KR) 10-2008-0092433

(51) Int. Cl. H04L 27/00; H03M 13/29

(52) U.S. Cl. 375/295; 375/316; 714/784

(57) ABSTRACT

A digital broadcasting system and a data processing method are disclosed. A receiving system of the digital broadcasting system comprises a baseband processor, a management processor and a presentation processor. The baseband processor receives a broadcast signal including mobile service data and main service data, wherein the mobile service data configure a Reed-Solomon (RS) frame. The RS frame includes at least one of the mobile service data and notification messages. The notification messages are packetized in accordance with any one of a first transport protocol and a second transport protocol. The management processor decodes the notification messages from the RS frame in accordance with any one of the first transport protocol and the second transport protocol. The presentation processor directly outputs the decoded notification messages to an output unit in accordance with a channel which transmits the decoded notification messages, or outputs the decoded notification messages to the output unit only if a user selects the notification messages.

This application claims the benefit of U.S. Provisional Application No. 60/974,084, filed on Sep. 21, 2007, which is hereby incorporated by reference. Also, this application claims the benefit of U.S. Provisional Application No. 60/977,379, filed on Oct. 4, 2007, which is hereby incorporated by reference. This application also claims the benefit of U.S. Provisional Application No. 61/044,504, filed on Apr. 13, 2008, which is hereby incorporated by reference. This application also claims the benefit of U.S. Provisional Application No. 61/076,686, filed on Jun. 29, 2008, which is hereby incorporated by reference. This application also claims the priority benefit of Korean Application No. 10-2008-0092433, filed on Sep. 19, 2008, which is hereby incorporated by reference.

### BACKGROUND OF THE INVENTION

1. Field of the Invention

The present invention relates to a digital broadcasting system and a method of processing data in a digital broadcasting system for transmitting and receiving digital broadcast signals.

2. Discussion of the Related Art

The Vestigial Sideband (VSB) transmission mode, which is adopted as the standard for digital broadcasting in North America and the Republic of Korea, is a system using a single carrier method. Therefore, the receiving performance of the digital broadcast receiving system may be deteriorated in a poor channel environment. Particularly, since resistance to changes in channels and noise is more highly required when using portable and/or mobile broadcast receivers, the receiving performance may be even more deteriorated when transmitting mobile service data by the VSB transmission mode.

### SUMMARY OF THE INVENTION

Accordingly, an object of the present invention is to provide a digital broadcasting system and a data processing method that are highly resistant to channel changes and noise.

Another object of the present invention is to provide a digital broadcasting system and a data processing method that can transmit and receive notification messages.

To achieve these objects and other advantages and in accordance with the purpose of the invention, as embodied and broadly described herein, a receiving system according to one embodiment of the present invention comprises a baseband processor, a management processor, and a presentation processor. The baseband processor receives a broadcast signal including mobile service data and main service data, wherein the mobile service data configure a Reed-Solomon (RS) frame. The RS frame includes at least one of the mobile service data and notification messages. The notification messages are packetized in accordance with any one of a first transport protocol and a second transport protocol. The management processor decodes the notification messages from the RS frame in accordance with any one of the first transport protocol and the second transport protocol. The presentation processor directly outputs the decoded notification messages to an output unit in accordance with a channel which transmits the decoded notification messages, or outputs the decoded notification messages to the output unit only if a user selects the notification messages.

The baseband processor further includes a known data detector detecting known data sequences included in at least one data group which configures the RS frame, and the detected known data sequences are used for demodulation and channel-equalization of the mobile service data.

The first transport protocol is a FLUTE protocol, and the second transport protocol is an RTP protocol.

The notification messages include a notification header and a notification payload, the notification header including identification information and position information, and the notification payload including identification information and notification contents, data of the notification header are received by being included in a file delivery table (FDT) of a FLUTE packet, and data of the notification payload are received by being included in a transport object part of the FLUTE packet.

The notification messages include a notification header and a notification payload, the notification header including identification information and position information, and the notification payload including identification information and notification contents, data of the notification header are received by being included in an RTP header of an RTP packet, and data of the notification payload are received by being included in an RTP payload part of the RTP packet.

In another aspect of the present invention, a data processing method of a receiving system comprises receiving a broadcast signal including mobile service data and main service data, wherein the mobile service data configure a Reed-Solomon (RS) frame, the RS frame including at least one of the mobile service data and notification messages, the notification messages being packetized in accordance with any one of a first transport protocol and a second transport protocol; decoding the notification messages from the RS frame in accordance with any one of the first transport protocol and the second transport protocol; and directly outputting the decoded notification messages to an output unit in accordance with a channel which transmits the decoded notification messages, or outputting the decoded notification messages to the output unit only if a user selects the notification messages.

Additional advantages, objects, and features of the invention may be realized and attained by the structure particularly pointed out in the written description as well as the appended drawings.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention.

In the drawings:

FIG. 1 illustrates a block diagram showing a general structure of a digital broadcasting receiving system according to an embodiment of the present invention;

FIG. 2 illustrates an exemplary structure of a data group according to the present invention;

FIG. 3 illustrates an RS frame according to an embodiment of the present invention;

FIG. 4 illustrates an example of an MH frame structure for transmitting and receiving mobile service data according to the present invention;

FIG. 5 illustrates an example of a general VSB frame structure;

FIG. 6 illustrates a example of mapping positions of the first 4 slots of a sub-frame in a spatial area with respect to a VSB frame;

FIG. 7 illustrates a example of mapping positions of the first 4 slots of a sub-frame in a chronological (or time) area with respect to a VSB frame;

FIG. 8 illustrates an exemplary order of data groups being assigned to one of 5 sub-frames configuring an MH frame according to the present invention;

FIG. 9 illustrates an example of a single parade being assigned to an MH frame according to the present invention;

FIG. 10 illustrates an example of 3 parades being assigned to an MH frame according to the present invention;

FIG. 11 illustrates an example of the process of assigning 3 parades shown in FIG. 10 being expanded to 5 sub-frames within an MH frame;

FIG. 12 illustrates a data transmission structure according to an embodiment of the present invention, wherein signaling data are included in a data group so as to be transmitted;

FIG. 13 illustrates a hierarchical signaling structure according to an embodiment of the present invention;

FIG. 14 illustrates an exemplary FIC body format according to an embodiment of the present invention;

FIG. 15 illustrates an exemplary bit stream syntax structure with respect to an FIC segment according to an embodiment of the present invention;

FIG. 16 illustrates an exemplary bit stream syntax structure with respect to a payload of an FIC segment according to the present invention, when an FIC type field value is equal to ‘0 ’;

FIG. 17 illustrates an exemplary bit stream syntax structure of a service map table according to the present invention;

FIG. 18 illustrates an exemplary bit stream syntax structure of an MH audio descriptor according to the present invention;

FIG. 19 illustrates an exemplary bit stream syntax structure of an MH RTP payload type descriptor according to the present invention;

FIG. 20 illustrates an exemplary bit stream syntax structure of an MH current event descriptor according to the present invention;

FIG. 21 illustrates an exemplary bit stream syntax structure of an MH next event descriptor according to the present invention;

FIG. 22 illustrates an exemplary bit stream syntax structure of an MH system time descriptor according to the present invention;

FIG. 23 illustrates segmentation and encapsulation processes of a service map table according to the present invention;

FIG. 24 illustrates a flow chart for accessing a virtual channel using FIC and SMT according to the present invention;

FIG. 25 illustrates an example of a protocol stack for serving notification messages based on IP;

FIG. 26 illustrates an example of a framework of notification messages according to the present invention;

FIG. 27 illustrates an example of a structure of a notification header of notification messages according to the present invention;

FIG. 28 illustrates an example of a structure of a notification payload of notification messages according to the present invention;

FIG. 29 illustrates an example of a structure of an RTP header for transferring notification messages to an RTP protocol in accordance with the present invention; and

FIG. 30 is a flow chart illustrating an example of a method of receiving and serving notification messages in accordance with the present invention.

### DETAILED DESCRIPTION OF THE INVENTION

Reference will now be made in detail to the preferred embodiments of the present invention, examples of which are illustrated in the accompanying drawings. Hereinafter, the preferred embodiment of the present invention will be described with reference to the accompanying drawings. At this time, it is to be understood that the following detailed description of the present invention illustrated in the drawings and described with reference to the drawings are exemplary and explanatory and technical spirits of the present invention and main features and operation of the present invention will not be limited by the following detailed description.

### DEFINITION OF THE TERMS USED IN THE PRESENT INVENTION

Although general terms, which are widely used considering functions in the present invention, have been selected in the present invention, they may be changed depending on intention of those skilled in the art, practices, or new technology. Also, in specific case, the applicant may optionally select the terms. In this case, the meaning of the terms will be described in detail in the description part of the invention. Therefore, it is to be understood that the terms should be defined based upon their meaning not their simple title and the whole description of the present invention.

Among the terms used in the description of the present invention, main service data correspond to data that can be received by a fixed receiving system and may include audio/video (A/V) data. More specifically, the main service data may include A/V data of high definition (HD) or standard definition (SD) levels and may also include diverse data types required for data broadcasting. Also, the known data correspond to data pre-known in accordance with a pre-arranged agreement between the receiving system and the transmitting system.

Additionally, among the terms used in the present invention, “MH” corresponds to the initials of “mobile” and “handheld” and represents the opposite concept of a fixed-type system. Furthermore, the MH service data may include at least one of mobile service data and handheld service data, and will also be referred to as “mobile service data” for simplicity. Herein, the mobile service data not only correspond to MH service data but may also include any type of service data with mobile or portable characteristics. Therefore, the mobile service data according to the present invention are not limited only to the MH service data.

The above-described mobile service data may correspond to data having information, such as program execution files, stock information, and so on, and may also correspond to A/V data. Most particularly, the mobile service data may correspond to A/V data having lower resolution and lower data rate as compared to the main service data. For example, if an A/V codec that is used for a conventional main service corresponds to a MPEG-2 codec, a MPEG-4 advanced video coding (AVC) or scalable video coding (SVC) having better image compression efficiency may be used as the A/V codec for the mobile service. Furthermore, any type of data may be transmitted as the mobile service data. For example, transport protocol expert group (TPEG) data for broadcasting real-time transportation information may be transmitted as the main service data.

Also, a data service using the mobile service data may include weather forecast services, traffic information services, stock information services, viewer participation quiz programs, real-time polls and surveys, interactive education broadcast programs, gaming services, services providing information on synopsis, character, background music, and filming sites of soap operas or series, services providing information on past match scores and player profiles and achievements, and services providing information on product information and programs classified by service, medium, time, and theme enabling purchase orders to be processed. Herein, the present invention is not limited only to the services mentioned above.

In the present invention, the transmitting system provides backward compatibility in the main service data so as to be received by the conventional receiving system. Herein, the main service data and the mobile service data are multiplexed to the same physical channel and then transmitted.

Furthermore, the transmitting system according to the present invention performs additional encoding on the mobile service data and inserts the data already known by the receiving system and transmitting system (e.g., known data), thereby transmitting the processed data.

Therefore, when using the transmitting system according to the present invention, the receiving system may receive the mobile service data during a mobile state and may also receive the mobile service data with stability despite various distortion and noise occurring within the channel.

Receiving System

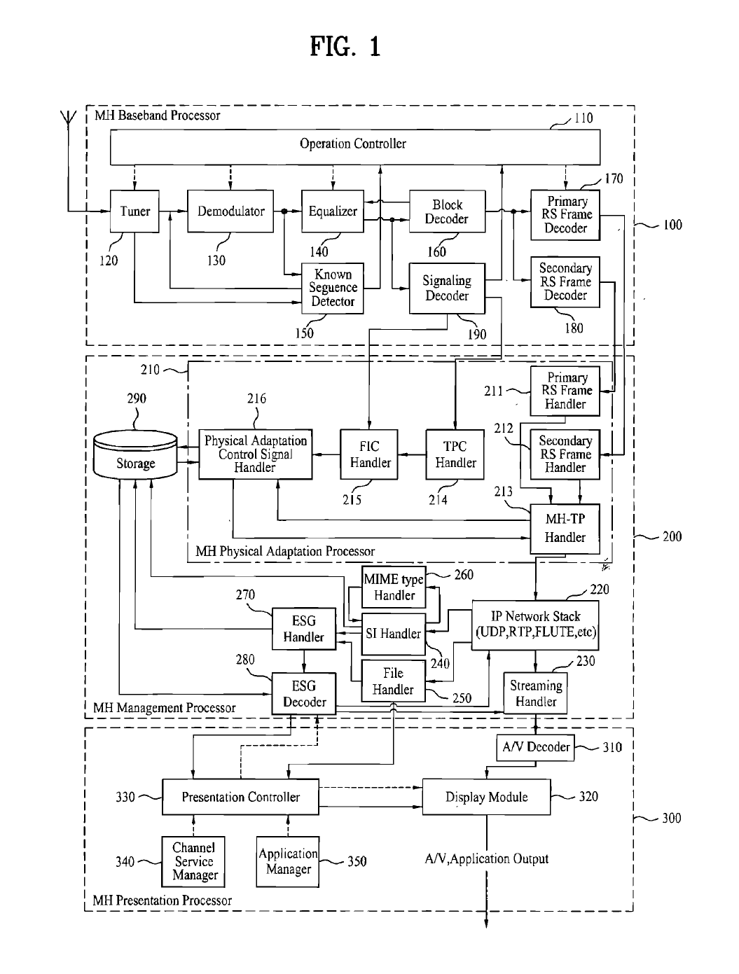

FIG. 1 illustrates a block diagram showing a general structure of a receiving system according to an embodiment of the present invention. The receiving system according to the present invention includes a baseband processor 100, a management processor 200, and a presentation processor 300.

The baseband processor 100 includes an operation controller 110, a tuner 120, a demodulator 130, an equalizer 140, a known sequence detector (or known data detector) 150, a block decoder (or mobile handheld block decoder) 160, a primary Reed-Solomon (RS) frame decoder 170, a secondary RS frame decoder 180, and a signaling decoder 190.

The operation controller 110 controls the operation of each block included in the baseband processor 100.

By tuning the receiving system to a specific physical channel frequency, the tuner 120 enables the receiving system to receive main service data, which correspond to broadcast signals for fixed-type broadcast receiving systems, and mobile service data, which correspond to broadcast signals for mobile broadcast receiving systems. At this point, the tuned frequency of the specific physical channel is down-converted to an intermediate frequency (IF) signal, thereby being outputted to the demodulator 130 and the known sequence detector 140. The passband digital IF signal being outputted from the tuner 120 may only include main service data, or only include mobile service data, or include both main service data and mobile service data.

The demodulator 130 performs self-gain control, carrier recovery, and timing recovery processes on the passband digital IF signal inputted from the tuner 120, thereby translating the IF signal to a baseband signal. Then, the demodulator 130 outputs the baseband signal to the equalizer 140 and the known sequence detector 150. The demodulator 130 uses the known data symbol sequence inputted from the known sequence detector 150 during the timing and/or carrier recovery, thereby enhancing the demodulating performance.

The equalizer 140 compensates channel-associated distortion included in the signal demodulated by the demodulator 130. Then, the equalizer 140 outputs the distortion-compensated signal to the block decoder 160. By using a known data symbol sequence inputted from the known sequence detector 150, the equalizer 140 may enhance the equalizing performance. Furthermore, the equalizer 140 may receive feed-back on the decoding result from the block decoder 160, thereby enhancing the equalizing performance.

The known sequence detector 150 detects known data place (or position) inserted by the transmitting system from the input/output data (i.e., data prior to being demodulated or data being processed with partial demodulation). Then, the known sequence detector 150 outputs the detected known data position information and known data sequence generated from the detected position information to the demodulator 130 and the equalizer 140. Additionally, in order to allow the block decoder 160 to identify the mobile service data that have been processed with additional encoding by the transmitting system and the main service data that have not been processed with any additional encoding, the known sequence detector 150 outputs such corresponding information to the block decoder 160.

If the data channel-equalized by the equalizer 140 and inputted to the block decoder 160 correspond to data processed with both block-encoding and trellis-encoding by the transmitting system (i.e., data within the RS frame, signaling data), the block decoder 160 may perform trellis-decoding and block-decoding as inverse processes of the transmitting system. On the other hand, if the data channel-equalized by the equalizer 140 and inputted to the block decoder 160 correspond to data processed only with trellis-encoding and not block-encoding by the transmitting system (i.e., main service data), the block decoder 160 may perform only trellis-decoding.

The signaling decoder 190 decoded signaling data that have been channel-equalized and inputted from the equalizer 140. It is assumed that the signaling data inputted to the signaling decoder 190 correspond to data processed with both block-encoding and trellis-encoding by the transmitting system. Examples of such signaling data may include transmission parameter channel (TPC) data and fast information channel (FIC) data. Each type of data will be described in more detail in a later process. The FIC data decoded by the signaling decoder 190 are outputted to the FIC handler 215. And, the TPC data decoded by the signaling decoder 190 are outputted to the TPC handler 214.

Meanwhile, according to the present invention, the transmitting system uses RS frames by encoding units. Herein, the RS frame may be divided into a primary RS frame and a secondary RS frame. However, according to the embodiment of the present invention, the primary RS frame and the secondary RS frame will be divided based upon the level of importance of the corresponding data.

The primary RS frame decoder 170 receives the data outputted from the block decoder 160. At this point, according to the embodiment of the present invention, the primary RS frame decoder 170 receives only the mobile service data that have been Reed-Solomon (RS)-encoded and/or cyclic redundancy check (CRC)-encoded from the block decoder 160. Herein, the primary RS frame decoder 170 receives only the mobile service data and not the main service data. The primary RS frame decoder 170 performs inverse processes of an RS frame encoder (not shown) included in the transmitting system, thereby correcting errors existing within the primary RS frame. More specifically, the primary RS frame decoder 170 forms a primary RS frame by grouping a plurality of data groups and, then, correct errors in primary RS frame units. In other words, the primary RS frame decoder 170 decodes primary RS frames, which are being transmitted for actual broadcast services.

Additionally, the secondary RS frame decoder 180 receives the data outputted from the block decoder 160. At this point, according to the embodiment of the present invention, the secondary RS frame decoder 180 receives only the mobile service data that have been RS-encoded and/or CRC-encoded from the block decoder 160. Herein, the secondary RS frame decoder 180 receives only the mobile service data and not the main service data. The secondary RS frame decoder 180 performs inverse processes of an RS frame encoder (not shown) included in the transmitting system, thereby correcting errors existing within the secondary RS frame. More specifically, the secondary RS frame decoder 180 forms a secondary RS frame by grouping a plurality of data groups and, then, correct errors in secondary RS frame units. In other words, the secondary RS frame decoder 180 decodes secondary RS frames, which are being transmitted for mobile audio service data, mobile video service data, guide data, and so on.

Meanwhile, the management processor 200 according to an embodiment of the present invention includes an MH physical adaptation processor 210, an IP network stack 220, a streaming handler 230, a system information (SI) handler 240, a file handler 250, a multi-purpose internet main extensions (MIME) type handler 260, and an electronic service guide (ESG) handler 270, and an ESG decoder 280, and a storage unit 290.

The MH physical adaptation processor 210 includes a primary RS frame handler 211, a secondary RS frame handler 212, an MH transport packet (TP) handler 213, a TPC handler 214, an FIC handler 215, and a physical adaptation control signal handler 216.

The TPC handler 214 receives and processes baseband information required by modules corresponding to the MH physical adaptation processor 210. The baseband information is inputted in the form of TPC data. Herein, the TPC handler 214 uses this information to process the FIC data, which have been sent from the baseband processor 100.

The TPC data are transmitted from the transmitting system to the receiving system via a predetermined region of a data group. The TPC data may include at least one of an MH ensemble ID, an MH sub-frame number, a total number of MH groups (TNoG), an RS frame continuity counter, a column size of RS frame (N), and an FIC version number.

Herein, the MH ensemble ID indicates an identification number of each MH ensemble carried in the corresponding channel.

The MH sub-frame number signifies a number identifying the MH sub-frame number in an MH frame, wherein each MH group associated with the corresponding MH ensemble is transmitted.

The TNoG represents the total number of MH groups including all of the MH groups belonging to all MH parades included in an MH sub-frame.

The RS frame continuity counter indicates a number that serves as a continuity counter of the RS frames carrying the corresponding MH ensemble. Herein, the value of the RS frame continuity counter shall be incremented by 1 modulo 16 for each successive RS frame.

N represents the column size of an RS frame belonging to the corresponding MH ensemble. Herein, the value of N determines the size of each MH TP.

Finally, the FIC version number signifies the version number of an FIC carried on the corresponding physical channel.

As described above, diverse TPC data are inputted to the TPC handler 214 via the signaling decoder 190 shown in FIG. 1. Then, the received TPC data are processed by the TPC handler 214. The received TPC data may also be used by the FIC handler 215 in order to process the FIC data.

The FIC handler 215 processes the FIC data by associating the FIC data received from the baseband processor 100 with the TPC data.

The physical adaptation control signal handler 216 collects FIC data received through the FIC handler 215 and SI data received through RS frames. Then, the physical adaptation control signal handler 216 uses the collected FIC data and SI data to configure and process IP datagrams and access information of mobile broadcast services. Thereafter, the physical adaptation control signal handler 216 stores the processed IP datagrams and access information to the storage unit 290.

The primary RS frame handler 211 identifies primary RS frames received from the primary RS frame decoder 170 of the baseband processor 100 for each row unit, so as to configure an MH TP. Thereafter, the primary RS frame handler 211 outputs the configured MH TP to the MH TP handler 213.

The secondary RS frame handler 212 identifies secondary RS frames received from the secondary RS frame decoder 180 of the baseband processor 100 for each row unit, so as to configure an MH TP. Thereafter, the secondary RS frame handler 212 outputs the configured MH TP to the MH TP handler 213.

The MH transport packet (TP) handler 213 extracts a header from each MH TP received from the primary RS frame handler 211 and the secondary RS frame handler 212, thereby determining the data included in the corresponding MH TP. Then, when the determined data correspond to SI data (i.e., SI data that are not encapsulated to IP datagrams), the corresponding data are outputted to the physical adaptation control signal handler 216. Alternatively, when the determined data correspond to an IP datagram, the corresponding data are outputted to the IP network stack 220.

The IP network stack 220 processes broadcast data that are being transmitted in the form of IP datagrams. More specifically, the IP network stack 220 processes data that are inputted via user datagram protocol (UDP), real-time transport protocol (RTP), real-time transport control protocol (RTCP), asynchronous layered coding/layered coding transport (ALC/LCT), file delivery over unidirectional transport (FLUTE), and so on. Herein, when the processed data correspond to streaming data, the corresponding data are outputted to the streaming handler 230. And, when the processed data correspond to data in a file format, the corresponding data are outputted to the file handler 250. Finally, when the processed data correspond to SI-associated data, the corresponding data are outputted to the SI handler 240.

The SI handler 240 receives and processes SI data having the form of IP datagrams, which are inputted to the IP network stack 220.

When the inputted data associated with SI correspond to MIME-type data, the inputted data are outputted to the MIME-type handler 260.

The MIME-type handler 260 receives the MIME-type SI data outputted from the SI handler 240 and processes the received MIME-type SI data.

The file handler 250 receives data from the IP network stack 220 in an object format in accordance with the ALC/LCT and FLUTE structures. The file handler 250 groups the received data to create a file format. Herein, when the corresponding file includes ESG, the file is outputted to the ESG handler 270. On the other hand, when the corresponding file includes data for other file-based services, the file is outputted to the presentation controller 330 of the presentation processor 300.

The ESG handler 270 processes the ESG data received from the file handler 250 and stores the processed ESG data to the storage unit 290. Alternatively, the ESG handler 270 may output the processed ESG data to the ESG decoder 280, thereby allowing the ESG data to be used by the ESG decoder 280.

The storage unit 290 stores the system information (SI) received from the physical adaptation control signal handler 210 and the ESG handler 270 therein. Thereafter, the storage unit 290 transmits the stored SI data to each block.

The ESG decoder 280 either recovers the ESG data and SI data stored in the storage unit 290 or recovers the ESG data transmitted from the ESG handler 270. Then, the ESG decoder 280 outputs the recovered data to the presentation controller 330 in a format that can be outputted to the user.

The streaming handler 230 receives data from the IP network stack 220, wherein the format of the received data are in accordance with RTP and/or RTCP structures. The streaming handler 230 extracts audio/video streams from the received data, which are then outputted to the audio/video (A/V) decoder 310 of the presentation processor 300. The audio/video decoder 310 then decodes each of the audio stream and video stream received from the streaming handler 230.

The display module 320 of the presentation processor 300 receives audio and video signals respectively decoded by the A/V decoder 310. Then, the display module 320 provides the received audio and video signals to the user through a speaker and/or a screen.

The presentation controller 330 corresponds to a controller managing modules that output data received by the receiving system to the user.

The channel service manager 340 manages an interface with the user, which enables the user to use channel-based broadcast services, such as channel map management, channel service connection, and so on.

The application manager 350 manages an interface with a user using ESG display or other application services that do not correspond to channel-based services.

Data Format Structure

Meanwhile, the data structure used in the mobile broadcasting technology according to the embodiment of the present invention may include a data group structure and an RS frame structure, which will now be described in detail.

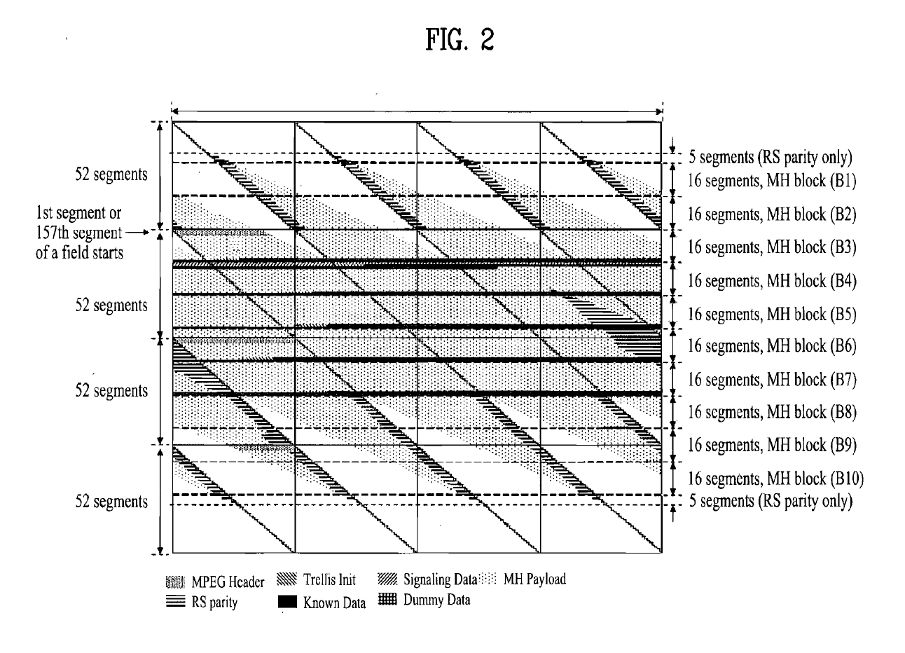

FIG. 2 illustrates an exemplary structure of a data group according to the present invention.

FIG. 2 shows an example of dividing a data group according to the data structure of the present invention into 10 MH blocks (i.e., MH block 1 (B1) to MH block 10 (B10)). In this example, each MH block has the length of 16 segments. Referring to FIG. 2, only the RS parity data are allocated to portions of the previous 5 segments of the MH block 1 (B1) and the next 5 segments of the MH block 10 (B10). The RS parity data are excluded in regions A to D of the data group.

More specifically, when it is assumed that one data group is divided into regions A, B, C, and D, each MH block may be included in any one of region A to region D depending upon the characteristic of each MH block within the data group. Herein, the data group is divided into a plurality of regions to be used for different purposes. More specifically, a region of the main service data having no interference or a very low interference level may be considered to have a more resistant (or stronger) receiving performance as compared to regions having higher interference levels. Additionally, when using a system inserting and transmitting known data in the data group, wherein the known data are known based upon an agreement between the transmitting system and the receiving system, and when consecutively long known data are to be periodically inserted in the mobile service data, the known data having a predetermined length may be periodically inserted in the region having no interference from the main service data (i.e., a region wherein the main service data are not mixed). However, due to interference from the main service data, it is difficult to periodically insert known data and also to insert consecutively long known data to a region having interference from the main service data.

Referring to FIG. 2, MH block 4 (B4) to MH block 7 (B7) correspond to regions without interference of the main service data. MH block 4 (B4) to MH block 7 (B7) within the data group shown in FIG. 2 correspond to a region where no interference from the main service data occurs. In this example, a long known data sequence is inserted at both the beginning and end of each MH block. In the description of the present invention, the region including MH block 4 (B4) to MH block 7 (B7) will be referred to as “region A (=B4+B5+B6+B7)”. As described above, when the data group includes region A having a long known data sequence inserted at both the beginning and end of each MH block, the receiving system is capable of performing equalization by using the channel information that can be obtained from the known data. Therefore, the strongest equalizing performance may be yielded (or obtained) from one of region A to region D.

In the example of the data group shown in FIG. 2, MH block (B3) and MH block 8 (B8) correspond to a region having little interference from the main service data. Herein, a long known data sequence is inserted in only one side of each MH block B3 and B8. More specifically, due to the interference from the main service data, a long known data sequence is inserted at the end of MH block 3 (B3), and another long known data sequence is inserted at the beginning of MH block 8 (B8). In the present invention, the region including MH block 3 (B3) and MH block 8 (B8) will be referred to as “region B (=B3+B8)”. As described above, when the data group includes region B having a long known data sequence inserted at only one side (beginning or end) of each MH block, the receiving system is capable of performing equalization by using the channel information that can be obtained from the known data. Therefore, a stronger equalizing performance as compared to region C/D may be yielded (or obtained).

Referring to FIG. 2, MH block 2 (B2) and MH block 9 (B9) correspond to a region having more interference from the main service data as compared to region B. A long known data sequence cannot be inserted in any side of MH block 2 (B2) and MH block 9 (B9). Herein, the region including MH block 2 (B2) and MH block 9 (B9) will be referred to as “region C (=B2+B9)”.

Finally, in the example shown in FIG. 2, MH block 1 (B1) and MH block 10 (B10) correspond to a region having more interference from the main service data as compared to region C. Similarly, a long known data sequence cannot be inserted in any side of MH block 1 (B1) and MH block 10 (B10). Herein, the region including MH block 1 (B1) and MH block 10 (B10) will be referred to as “region D (=B1+B10)”. Since region C/D is spaced further apart from the known data sequence, when the channel environment undergoes frequent and abrupt changes, the receiving performance of region C/D may be deteriorated.

Additionally, the data group includes a signaling information area wherein signaling information is assigned (or allocated).

In the present invention, the signaling information area may start from the 1^{st} segment of the 4^{th} MH block (B4) to a portion of the 2^{nd} segment. According to an embodiment of the present invention, the signaling information area for inserting signaling information may start from the 1^{st} segment of the 4^{th} MH block (B4) to a portion of the 2^{nd} segment.

More specifically, 276(=207+69) bytes of the 4^{th} MH block (B4) in each data group are assigned as the signaling information area. In other words, the signaling information area consists of 207 bytes of the 1^{st} segment and the first 69 bytes of the 2^{nd} segment of the 4^{th} MH block (B4). The 1^{st} segment of the 4^{th} MH block (B4) corresponds to the 17^{th} or 173^{rd} segment of a VSB field.

Herein, the signaling information may be identified by two different types of signaling channels: a transmission parameter channel (TPC) and a fast information channel (FIC).

Herein, the TPC data may include at least one of an MH ensemble ID, an MH sub-frame number, a total number of MH groups (TNoG), an RS frame continuity counter, a column size of RS frame (N), and an FIC version number. However, the TPC data (or information) presented herein are merely exemplary. And, since the adding or deleting of signaling information included in the TPC data may be easily adjusted and modified by one skilled in the art, the present invention will, therefore, not be limited to the examples set forth herein. Furthermore, the FIC is provided to enable a fast service acquisition of data receivers, and the FIC includes cross layer information between the physical layer and the upper layer(s).

For example, when the data group includes 6 known data sequences, as shown in FIG. 2, the signaling information area is located between the first known data sequence and the second known data sequence. More specifically, the first known data sequence is inserted in the last 2 segments of the 3^{rd} MH block (B3), and the second known data sequence in inserted in the 2^{nd} and 3^{rd} segments of the 4^{th} MH block (B4). Furthermore, the 3^{rd} to 6^{th} known data sequences are respectively inserted in the last 2 segments of each of the 4^{th}, 5^{th}, 6^{th}, and 7^{th} MH blocks (B4, B5, B6, and B7). The 1^{st} and 3^{rd} to 6^{th} known data sequences are spaced apart by 16 segments.

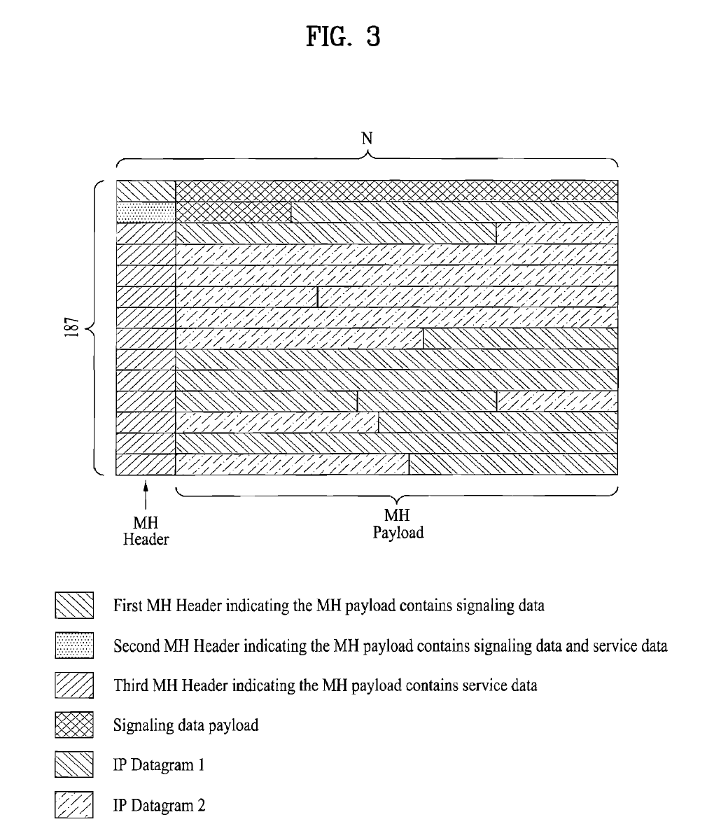

FIG. 3 illustrates an RS frame according to an embodiment of the present invention.

The RS frame shown in FIG. 3 corresponds to a collection of one or more data groups. The RS frame is received for each MH frame in a condition where the receiving system receives the FIC and processes the received FIC and where the receiving system is switched to a time-slicing mode so that the receiving system can receive MH ensembles including ESG entry points. Each RS frame includes IP streams of each service or ESG, and SMT section data may exist in all RS frames.

The RS frame according to the embodiment of the present invention consists of at least one MH transport packet (TP). Herein, the MH TP includes an MH header and an MH payload.

The MH payload may include mobile service data as well as signaling data. More specifically, an MH payload may include only mobile service data, or may include only signaling data, or may include both mobile service data and signaling data.

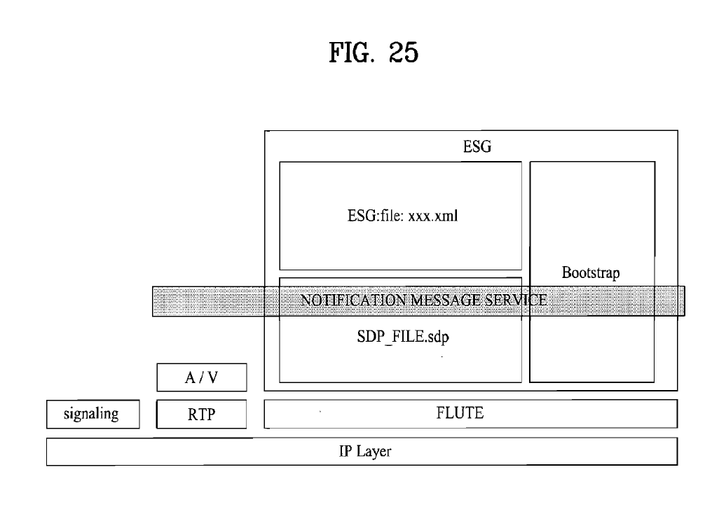

According to the embodiment of the present invention, the MH header may identify (or distinguish) the data types included in the MH payload. More specifically, when the MH TP includes a first MH header, this indicates that the MH payload includes only the signaling data. Also, when the MH TP includes a second MH header, this indicates that the MH payload includes both the signaling data and the mobile service data. Finally, when MH TP includes a third MH header, this indicates that the MH payload includes only the mobile service data. Signaling information within the MP payload may further include data on an IP signaling channel having well-known access information. More specifically, at least a portion of the signaling data may be transmitted (or delivered) through the IP signaling channel. The IP signaling channel will be described in more detail later on with reference to FIG. 25.

In the example shown in FIG. 3, the RS frame is assigned with IP datagrams (IP datagram 1 and IP datagram 2) for two service types.

Data Transmission Structure

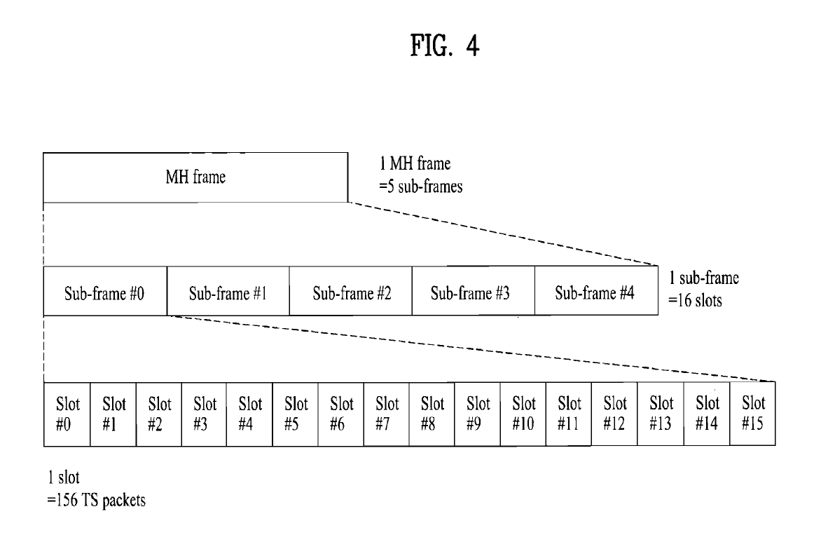

FIG. 4 illustrates a structure of a MH frame for transmitting and receiving mobile service data according to the present invention. In the example shown in FIG. 4, one MH frame consists of 5 sub-frames, wherein each sub-frame includes 16 slots. In this case, the MH frame according to the present invention includes 5 sub-frames and 80 slots.

Also, in a packet level, one slot is configured of 156 data packets (i.e., transport stream packets), and in a symbol level, one slot is configured of 156 data segments. Herein, the size of one slot corresponds to one half (½) of a VSB field. More specifically, since one 207-byte data packet has the same amount of data as a data segment, a data packet prior to being interleaved may also be used as a data segment. At this point, two VSB fields are grouped to form a VSB frame.

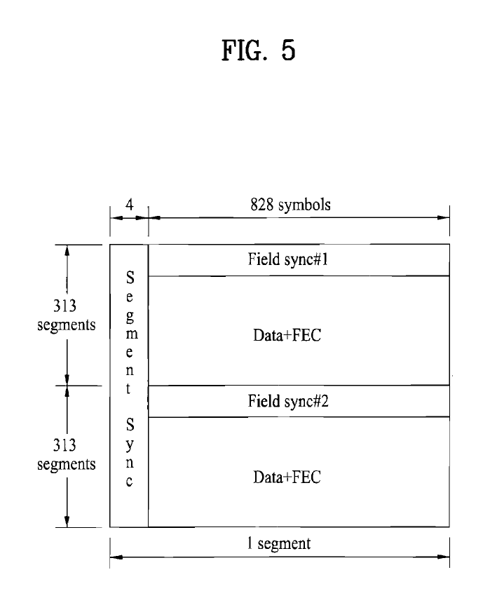

FIG. 5 illustrates an exemplary structure of a VSB frame, wherein one VSB frame consists of 2 VSB fields (i.e., an odd field and an even field). Herein, each VSB field includes a field synchronization segment and 312 data segments.

The slot corresponds to a basic time unit for multiplexing the mobile service data and the main service data. Herein, one slot may either include the mobile service data or be configured only of the main service data.

If the first 118 data packets within the slot correspond to a data group, the remaining 38 data packets become the main service data packets. In another example, when no data group exists in a slot, the corresponding slot is configured of 156 main service data packets.

Meanwhile, when the slots are assigned to a VSB frame, an off-set exists for each assigned position.

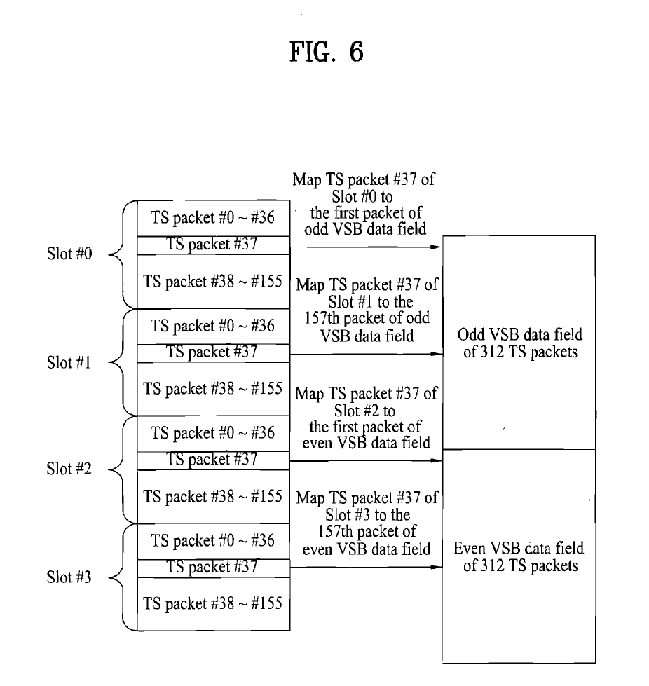

FIG. 6 illustrates a mapping example of the positions to which the first 4 slots of a sub-frame are assigned with respect to a VSB frame in a spatial area. And, FIG. 7 illustrates a mapping example of the positions to which the first 4 slots of a sub-frame are assigned with respect to a VSB frame in a chronological (or time) area.

Referring to FIG. 6 and FIG. 7, a 38^{th} data packet (TS packet #37) of a 1^{st} slot (Slot #0) is mapped to the 1^{st} data packet of an odd VSB field. A 38^{th} data packet (TS packet #37) of a 2^{nd} slot (Slot #1) is mapped to the 157^{th} data packet of an odd VSB field. Also, a 38^{th} data packet (TS packet #37) of a 3^{rd} slot (Slot #2) is mapped to the 1^{st} data packet of an even VSB field. And, a 38^{th} data packet (TS packet #37) of a 4^{th} slot (Slot #3) is mapped to the 157^{th} data packet of an even VSB field. Similarly, the remaining 12 slots within the corresponding sub-frame are mapped in the subsequent VSB frames using the same method.

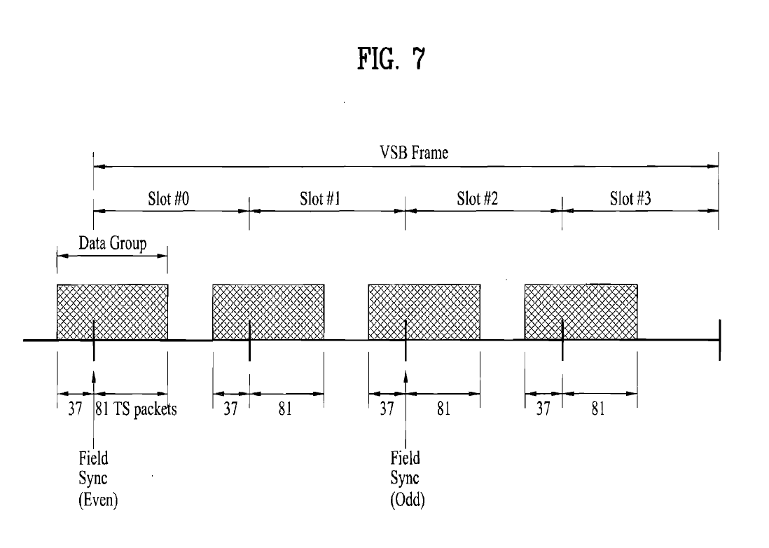

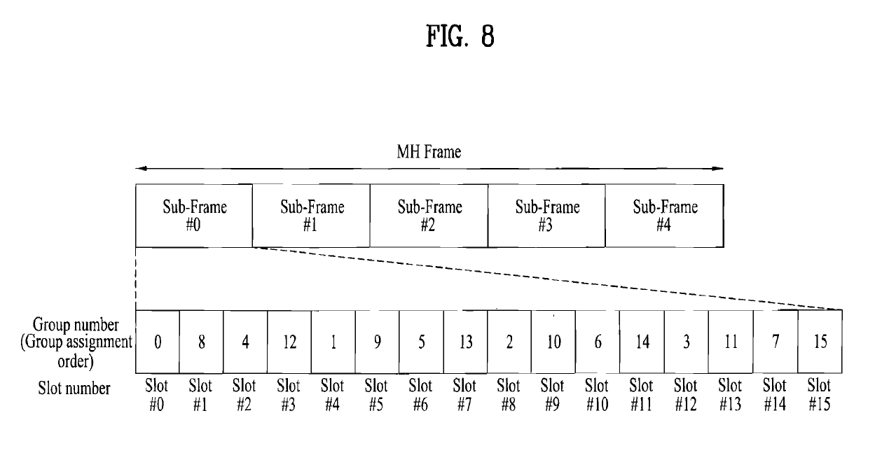

FIG. 8 illustrates an exemplary assignment order of data groups being assigned to one of 5 sub-frames, wherein the 5 sub-frames configure an MH frame. For example, the method of assigning data groups may be identically applied to all MH frames or differently applied to each MH frame. Furthermore, the method of assigning data groups may be identically applied to all sub-frames or differently applied to each sub-frame. At this point, when it is assumed that the data groups are assigned using the same method in all sub-frames of the corresponding MH frame, the total number of data groups being assigned to an MH frame is equal to a multiple of ‘5’.

According to the embodiment of the present invention, a plurality of consecutive data groups is assigned to be spaced as far apart from one another as possible within the sub-frame. Thus, the system can be capable of responding promptly and effectively to any burst error that may occur within a sub-frame.

For example, when it is assumed that 3 data groups are assigned to a sub-frame, the data groups are assigned to a 1^{st} slot (Slot #0), a 5^{th} slot (Slot #4), and a 9^{th} slot (Slot #8) in the sub-frame, respectively. FIG. 8 illustrates an example of assigning 16 data groups in one sub-frame using the above-described pattern (or rule). In other words, each data group is serially assigned to 16 slots corresponding to the following numbers: 0, 8, 4, 12, 1, 9, 5, 13, 2, 10, 6, 14, 3, 11, 7, and 15. Equation 1 below shows the above-described rule (or pattern) for assigning data groups in a sub-frame.

$$j = ( 4 i + 0 ) mod 16 Herein , \begin{matrix}0 = 0 if i < 4 , \\ 0 = 2 else if i < 8 , \\ 0 = 1 else if i < 12 , \\ 0 = 3 else .\end{matrix} \qquad Equation 1$$

Herein, j indicates the slot number within a sub-frame. The value of j may range from 0 to 15 (i.e., 0≦j≦15). Also, variable i indicates the data group number. The value of i may range from 0 to 15 (i.e., 0≦i≦15).

In the present invention, a collection of data groups included in a MH frame will be referred to as a “parade”. Based upon the RS frame mode, the parade transmits data of at least one specific RS frame.

The mobile service data within one RS frame may be assigned either to all of regions A/B/C/D within the corresponding data group, or to at least one of regions A/B/C/D. In the embodiment of the present invention, the mobile service data within one RS frame may be assigned either to all of regions A/B/C/D, or to at least one of regions A/B and regions C/D. If the mobile service data are assigned to the latter case (i.e., one of regions A/B and regions C/D), the RS frame being assigned to regions A/B and the RS frame being assigned to regions C/D within the corresponding data group are different from one another. According to the embodiment of the present invention, the RS frame being assigned to regions A/B within the corresponding data group will be referred to as a “primary RS frame”, and the RS frame being assigned to regions C/D within the corresponding data group will be referred to as a “secondary RS frame”, for simplicity. Also, the primary RS frame and the secondary RS frame form (or configure) one parade. More specifically, when the mobile service data within one RS frame are assigned either to all of regions A/B/C/D within the corresponding data group, one parade transmits one RS frame. Conversely, when the mobile service data within one RS frame are assigned either to at least one of regions A/B and regions C/D, one parade may transmit up to 2 RS frames.

More specifically, the RS frame mode indicates whether a parade transmits one RS frame, or whether the parade transmits two RS frames. Such RS frame mode is transmitted as the above-described TPC data.

Table 1 below shows an example of the RS frame mode.

TABLE 1

| RS frame | |
|---|---|
| mode | |
| (2 bits) | Description |
| 00 | There is only one primary RS frame for |
| | all group regions |
| 01 | There are two separate RS frames. |
| | Primary RS frame for group regions A and B |
| | Secondary RS frame for group regions C and D |
| 10 | Reserved |
| 11 | Reserved |

Table 1 illustrates an example of allocating 2 bits in order to indicate the RS frame mode. For example, referring to Table 1, when the RS frame mode value is equal to ‘00 ’, this indicates that one parade transmits one RS frame. And, when the RS frame mode value is equal to ‘01 ’, this indicates that one parade transmits two RS frames, i.e., the primary RS frame and the secondary RS frame. More specifically, when the RS frame mode value is equal to ‘01 ’, data of the primary RS frame for regions A/B are assigned and transmitted to regions A/B of the corresponding data group. Similarly, data of the secondary RS frame for regions C/D are assigned and transmitted to regions C/D of the corresponding data group.

As described in the assignment of data groups, the parades are also assigned to be spaced as far apart from one another as possible within the sub-frame. Thus, the system can be capable of responding promptly and effectively to any burst error that may occur within a sub-frame.

Furthermore, the method of assigning parades may be identically applied to all MH frames or differently applied to each MH frame. According to the embodiment of the present invention, the parades may be assigned differently for each MH frame and identically for all sub-frames within an MH frame. More specifically, the MH frame structure may vary by MH frame units. Thus, an ensemble rate may be adjusted on a more frequent and flexible basis.

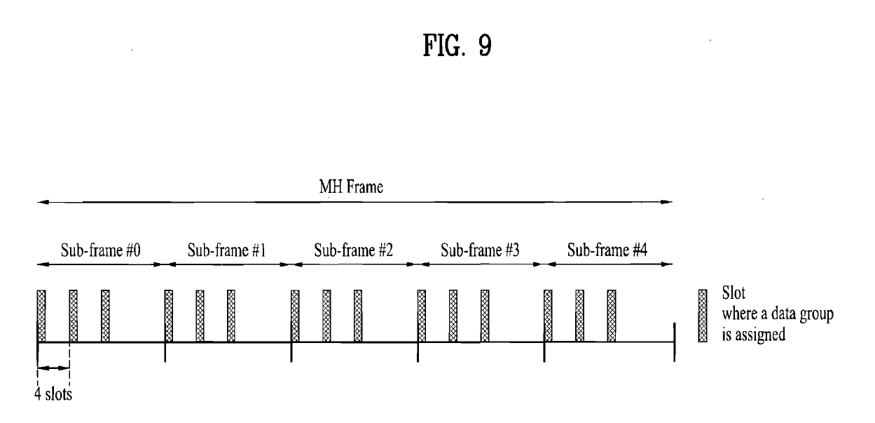

FIG. 9 illustrates an example of multiple data groups of a single parade being assigned (or allocated) to an MH frame.

More specifically, FIG. 9 illustrates an example of a plurality of data groups included in a single parade, wherein the number of data groups included in a sub-frame is equal to ‘3 ’, being allocated to an MH frame.

Referring to FIG. 9, 3 data groups are sequentially assigned to a sub-frame at a cycle period of 4 slots. Accordingly, when this process is equally performed in the 5 sub-frames included in the corresponding MH frame, 15 data groups are assigned to a single MH frame. Herein, the 15 data groups correspond to data groups included in a parade. Therefore, since one sub-frame is configured of 4 VSB frame, and since 3 data groups are included in a sub-frame, the data group of the corresponding parade is not assigned to one of the 4 VSB frames within a sub-frame.

For example, when it is assumed that one parade transmits one RS frame, and that a RS frame encoder (not shown) included in the transmitting system performs RS-encoding on the corresponding RS frame, thereby adding 24 bytes of parity data to the corresponding RS frame and transmitting the processed RS frame, the parity data occupy approximately 11.37% (=24/(187+24)×100) of the total code word length. Meanwhile, when one sub-frame includes 3 data groups, and when the data groups included in the parade are assigned, as shown in FIG. 9, a total of 15 data groups form an RS frame. Accordingly, even when an error occurs in an entire data group due to a burst noise within a channel, the percentile is merely 6.67% (=1/15×100). Therefore, the receiving system may correct all errors by performing an erasure RS decoding process. More specifically, when the erasure RS decoding is performed, a number of channel errors corresponding to the number of RS parity bytes may be corrected. By doing so, the receiving system may correct the error of at least one data group within one parade. Thus, the minimum burst noise length correctable by a RS frame is over 1 VSB frame.

Meanwhile, when data groups of a parade are assigned as shown in FIG. 9, either main service data may be assigned between each data group, or data groups corresponding to different parades may be assigned between each data group. More specifically, data groups corresponding to multiple parades may be assigned to one MH frame.

Basically, the method of assigning data groups corresponding to multiple parades is very similar to the method of assigning data groups corresponding to a single parade. In other words, data groups included in other parades that are to be assigned to an MH frame are also respectively assigned according to a cycle period of 4 slots.

At this point, data groups of a different parade may be sequentially assigned to the respective slots in a circular method. Herein, the data groups are assigned to slots starting from the ones to which data groups of the previous parade have not yet been assigned.

For example, when it is assumed that data groups corresponding to a parade are assigned as shown in FIG. 9, data groups corresponding to the next parade may be assigned to a sub-frame starting either from the 12^{th} slot of a sub-frame. However, this is merely exemplary. In another example, the data groups of the next parade may also be sequentially assigned to a different slot within a sub-frame at a cycle period of 4 slots starting from the 3^{rd} slot.

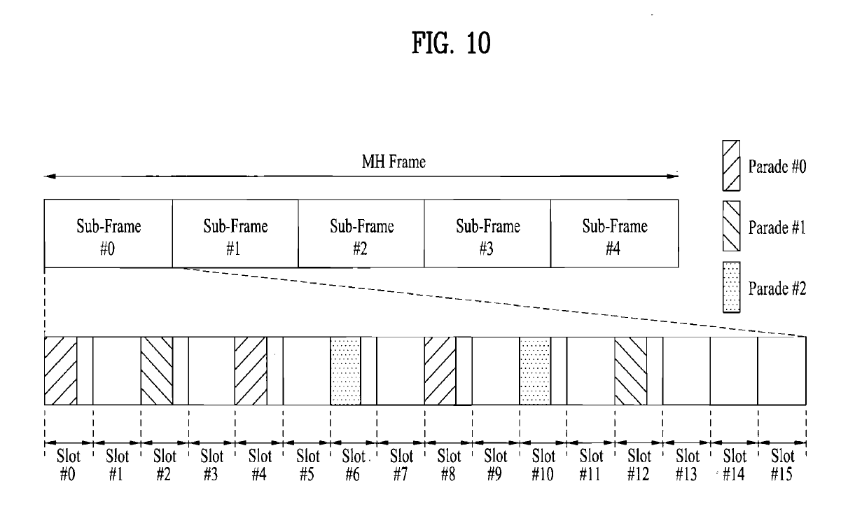

FIG. 10 illustrates an example of transmitting 3 parades (Parade #0, Parade #1, and Parade #2) to an MH frame. More specifically, FIG. 10 illustrates an example of transmitting parades included in one of 5 sub-frames, wherein the 5 sub-frames configure one MH frame.

When the 1^{st} parade (Parade #0) includes 3 data groups for each sub-frame, the positions of each data groups within the sub-frames may be obtained by substituting values ‘0 ’ to ‘2 ’ for i in Equation 1. More specifically, the data groups of the 1^{st} parade (Parade #0) are sequentially assigned to the 1^{st}, 5^{th}, and 9^{th} slots (Slot #0, Slot #4, and Slot #8) within the sub-frame.

Also, when the 2^{nd} parade includes 2 data groups for each sub-frame, the positions of each data groups within the sub-frames may be obtained by substituting values ‘3 ’ and ‘4 ’ for in Equation 1. More specifically, the data groups of the 2^{nd} parade (Parade #1) are sequentially assigned to the 2^{nd} and 12^{th} slots (Slot #1 and Slot #11) within the sub-frame.

Finally, when the 3^{rd} parade includes 2 data groups for each sub-frame, the positions of each data groups within the sub-frames may be obtained by substituting values ‘5 ’ and ‘6 ’ for i in Equation 1. More specifically, the data groups of the 3^{rd} parade (Parade #2) are sequentially assigned to the 7^{th} and 11^{th} slots (Slot #6 and Slot #10) within the sub-frame.

As described above, data groups of multiple parades may be assigned to a single MH frame, and, in each sub-frame, the data groups are serially allocated to a group space having 4 slots from left to right.

Therefore, a number of groups of one parade per sub-frame (NoG) may correspond to any one integer from ‘1 ’ to ‘8 ’. Herein, since one MH frame includes 5 sub-frames, the total number of data groups within a parade that can be allocated to an MH frame may correspond to any one multiple of ‘5 ’ ranging from ‘5 ’ to ‘40’.

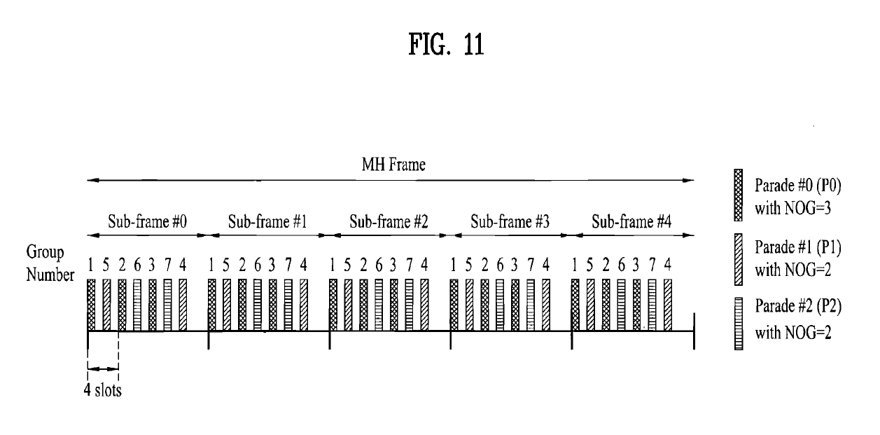

FIG. 11 illustrates an example of expanding the assignment process of 3 parades, shown in FIG. 10, to 5 sub-frames within an MH frame.

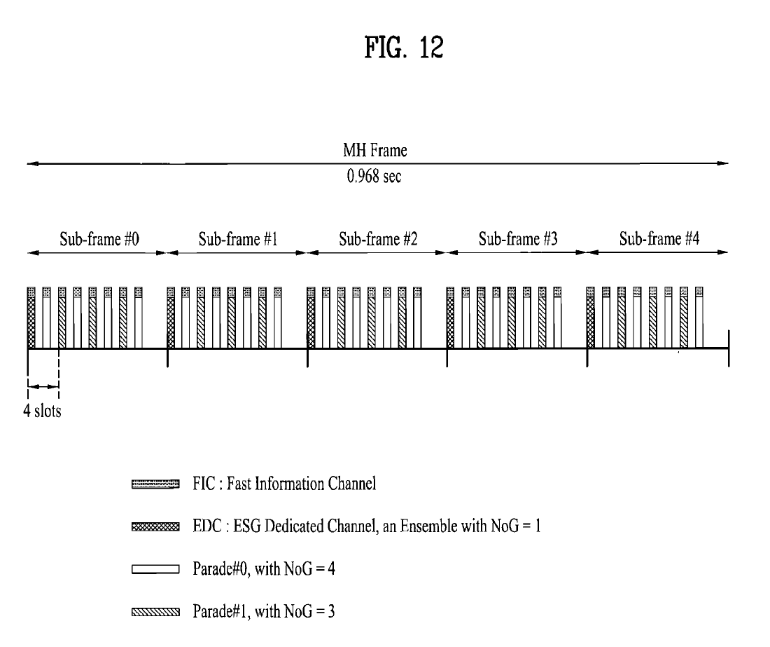

FIG. 12 illustrates a data transmission structure according to an embodiment of the present invention, wherein signaling data are included in a data group so as to be transmitted.

As described above, an MH frame is divided into 5 sub-frames. Data groups corresponding to a plurality of parades co-exist in each sub-frame. Herein, the data groups corresponding to each parade are grouped by MH frame units, thereby configuring a single parade.

The data structure shown in FIG. 12 includes 3 parades, one ESG dedicated channel (EDC) parade (i.e., parade with NoG=1), and 2 service parades (i.e., parade with NoG=4 and parade with NoG=3). Also, a predetermined portion of each data group (i.e., 37 bytes/data group) is used for delivering (or sending) FIC information associated with mobile service data, wherein the FIC information is separately encoded from the RS-encoding process. The FIC region assigned to each data group consists of one FIC segments. Herein, each segment is interleaved by MH sub-frame units, thereby configuring an FIC body, which corresponds to a completed FIC transmission structure. However, whenever required, each segment may be interleaved by MH frame units and not by MH sub-frame units, thereby being completed in MH frame units.

Meanwhile, the concept of an MH ensemble is applied in the embodiment of the present invention, thereby defining a collection (or group) of services. Each MH ensemble carries the same QoS and is coded with the same FEC code. Also, each MH ensemble has the same unique identifier (i.e., ensemble ID) and corresponds to consecutive RS frames.

As shown in FIG. 12, the FIC segment corresponding to each data group described service information of an MH ensemble to which the corresponding data group belongs. When FIC segments within a sub-frame are grouped and deinterleaved, all service information of a physical channel through which the corresponding FICs are transmitted may be obtained. Therefore, the receiving system may be able to acquire the channel information of the corresponding physical channel, after being processed with physical channel tuning, during a sub-frame period.

Furthermore, FIG. 12 illustrates a structure further including a separate EDC parade apart from the service parade and wherein electronic service guide (ESG) data are transmitted in the 1^{St} slot of each sub-frame.

Hierarchical Signaling Structure

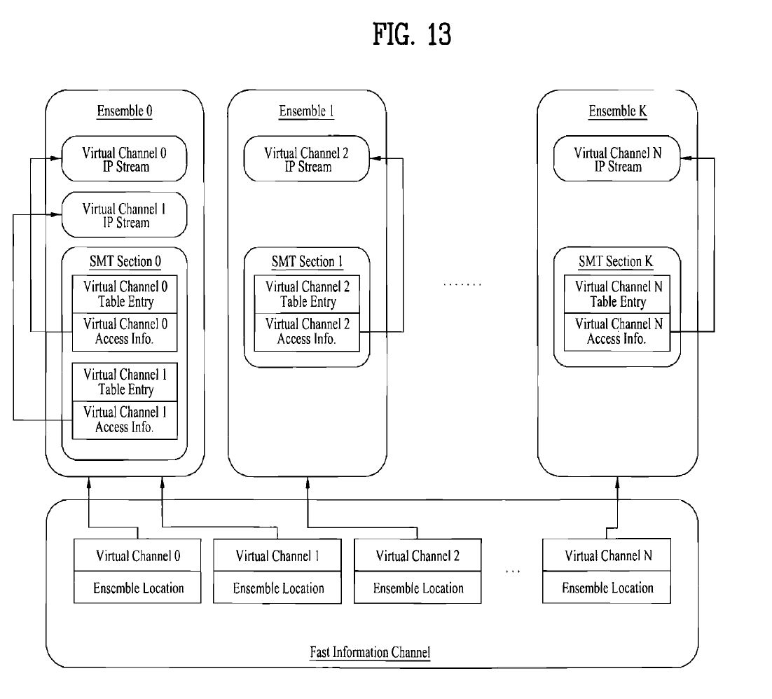

FIG. 13 illustrates a hierarchical signaling structure according to an embodiment of the present invention. As shown in FIG. 13, the mobile broadcasting technology according to the embodiment of the present invention adopts a signaling method using FIC and SMT. In the description of the present invention, the signaling structure will be referred to as a hierarchical signaling structure.

Hereinafter, a detailed description on how the receiving system accesses a virtual channel via FIC and SMT will now be given with reference to FIG. 13. Herein, the SMT corresponds to one of multiple signaling tables being received through the IP signaling channel of the corresponding RS frame.

The FIC body defined in an MH transport (M1) identifies the physical location of each the data stream for each virtual channel and provides very high level descriptions of each virtual channel.

Being MH ensemble level signaling information, the service map table (SMT) provides MH ensemble level signaling information. The SMT provides the IP access information of each virtual channel belonging to the respective MH ensemble within which the SMT is carried. The SMT also provides all IP stream component level information required for the virtual channel service acquisition.

Referring to FIG. 13, each MH ensemble (i.e., Ensemble 0, Ensemble 1, . . . , Ensemble K) includes a stream information on each associated (or corresponding) virtual channel (e.g., virtual channel 0 IP stream, virtual channel 1 IP stream, and virtual channel 2 IP stream). For example, Ensemble 0 includes virtual channel 0 IP stream and virtual channel 1 IP stream. And, each MH ensemble includes diverse information on the associated virtual channel (i.e., Virtual Channel 0 Table Entry, Virtual Channel 0 Access Info, Virtual Channel 1 Table Entry, Virtual Channel 1 Access Info, Virtual Channel 2 Table Entry, Virtual Channel 2 Access Info, Virtual Channel N Table Entry, Virtual Channel N Access Info, and so on).

The FIC body payload includes information on MH ensembles (e.g., ensemble_id field, and referred to as “ensemble location” in FIG. 13) and information on a virtual channel associated with the corresponding MH ensemble (e.g., when such information corresponds to a major_channel_num field and a minor_channel_num field, the information is expressed as Virtual Channel 0, Virtual Channel 1, . . . , Virtual Channel N in FIG. 13).

The application of the signaling structure in the receiving system will now be described in detail.

When a user selects a channel he or she wishes to view (hereinafter, the user-selected channel will be referred to as “channel θ” for simplicity), the receiving system first parses the received FIC. Then, the receiving system acquires information on an MH ensemble (i.e., ensemble location), which is associated with the virtual channel corresponding to channel θ (hereinafter, the corresponding MH ensemble will be referred to as “MH ensemble θ” for simplicity). By acquiring slots only corresponding to the MH ensemble θ using the time-slicing method, the receiving system configures ensemble θ. The ensemble θ configured as described above, includes an SMT on the associated virtual channels (including channel θ) and IP streams on the corresponding virtual channels. Therefore, the receiving system uses the SMT included in the MH ensemble θ in order to acquire various information on channel θ (e.g., Virtual Channel θ Table Entry) and stream access information on channel θ (e.g., Virtual Channel θ Access Info). The receiving system uses the stream access information on channel θ to receive only the associated IP streams, thereby providing channel θ services to the user.

Fast Information Channel (FIC)

The digital broadcast receiving system according to the present invention adopts the fast information channel (FIC) for a faster access to a service that is currently being broadcasted.

More specifically, the FIC handler 215 of FIG. 1 parses the FIC body, which corresponds to an FIC transmission structure, and outputs the parsed result to the physical adaptation control signal handler 216.

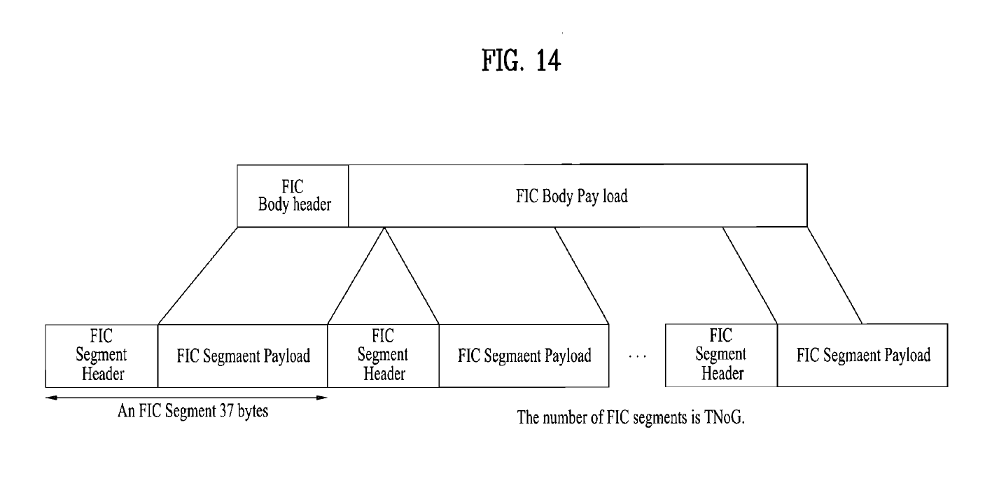

FIG. 14 illustrates an exemplary FIC body format according to an embodiment of the present invention. According to the embodiment of the present invention, the FIC format consists of an FIC body header and an FIC body payload.

Meanwhile, according to the embodiment of the present invention, data are transmitted through the FIC body header and the FIC body payload in FIC segment units. Each FIC segment has the size of 37 bytes, and each FIC segment consists of a 2-byte FIC segment header and a 35-byte FIC segment payload. More specifically, an FIC body configured of an FIC body header and an FIC body payload, is segmented in units of 35 data bytes, which are then carried in at least one FIC segment within the FIC segment payload, so as to be transmitted.

In the description of the present invention, an example of inserting one FIC segment in one data group, which is then transmitted, will be given. In this case, the receiving system receives a slot corresponding to each data group by using a time-slicing method.

The signaling decoder 190 included in the receiving system shown in FIG. 1 collects each FIC segment inserted in each data group. Then, the signaling decoder 190 uses the collected FIC segments to created a single FIC body. Thereafter, the signaling decoder 190 performs a decoding process on the FIC body payload of the created FIC body, so that the decoded FIC body payload corresponds to an encoded result of a signaling encoder (not shown) included in the transmitting system. Subsequently, the decoded FIC body payload is outputted to the FIC handler 215. The FIC handler 215 parses the FIC data included in the FIC body payload, and then outputs the parsed FIC data to the physical adaptation control signal handler 216. The physical adaptation control signal handler 216 uses the inputted FIC data to perform processes associated with MH ensembles, virtual channels, SMTs, and so on.

According to an embodiment of the present invention, when an FIC body is segmented, and when the size of the last segmented portion is smaller than 35 data bytes, it is assumed that the lacking number of data bytes in the FIC segment payload is completed with by adding the same number of stuffing bytes therein, so that the size of the last FIC segment can be equal to 35 data bytes.

However, it is apparent that the above-described data byte values (i.e., 37 bytes for the FIC segment, 2 bytes for the FIC segment header, and 35 bytes for the FIC segment payload) are merely exemplary, and will, therefore, not limit the scope of the present invention.

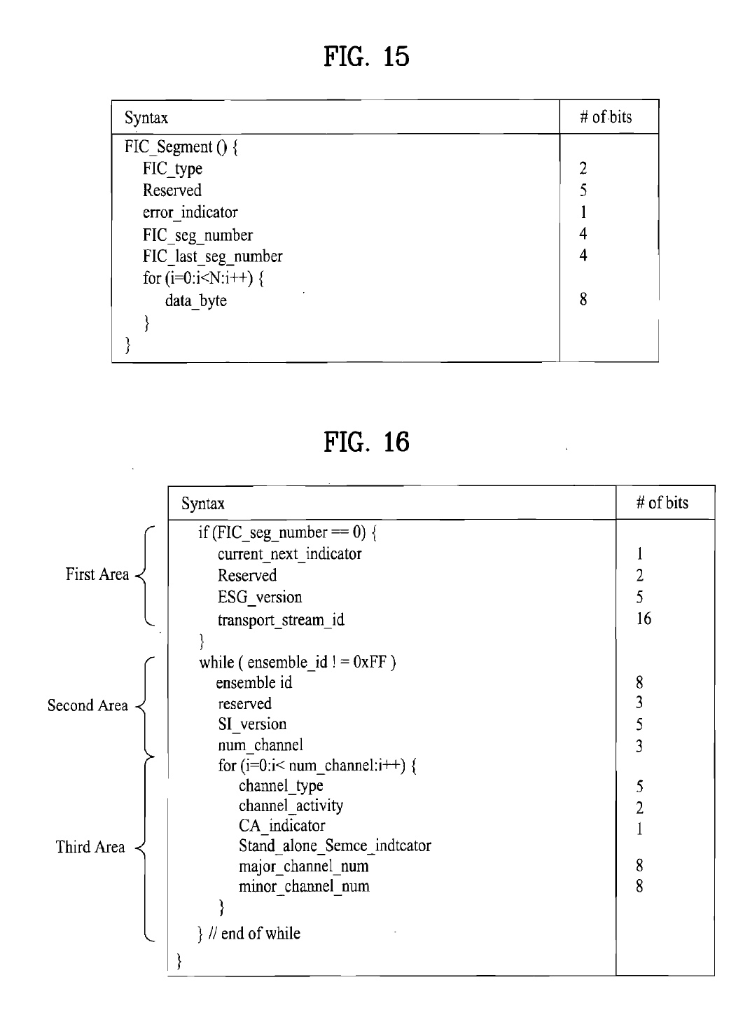

FIG. 15 illustrates an exemplary bit stream syntax structure with respect to an FIC segment according to an embodiment of the present invention.

Herein, the FIC segment signifies a unit used for transmitting the FIC data. The FIC segment consists of an FIC segment header and an FIC segment payload. Referring to FIG. 15, the FIC segment payload corresponds to the portion starting from the ‘for’ loop statement. Meanwhile, the FIC segment header may include a FIC_type field, an error_indicator field, an FIC_seg_number field, and an FIC_last_seg number field. A detailed description of each field will now be given.

The FIC_type field is a 2-bit field indicating the type of the corresponding FIC.

The error_indicator field is a 1-bit field, which indicates whether or not an error has occurred within the FIC segment during data transmission. If an error has occurred, the value of the error_indicator field is set to ‘1 ’. More specifically, when an error that has failed to be recovered still remains during the configuration process of the FIC segment, the error_indicator field value is set to ‘1 ’. The error_indicator field enables the receiving system to recognize the presence of an error within the FIC data.

The FIC_seg_number field is a 4-bit field. Herein, when a single FIC body is divided into a plurality of FIC segments and transmitted, the FIC_seg_number field indicates the number of the corresponding FIC segment.

Finally, the FIC_last_seg number field is also a 4-bit field. The FIC_last_seg number field indicates the number of the last FIC segment within the corresponding FIC body.

FIG. 16 illustrates an exemplary bit stream syntax structure with respect to a payload of an FIC segment according to the present invention, when an FIC type field value is equal to ‘0’.

According to the embodiment of the present invention, the payload of the FIC segment is divided into 3 different regions.

A first region of the FIC segment payload exists only when the FIC_seg_number field value is equal to ‘0 ’. Herein, the first region may include a current_next_indicator field, an ESG_version field, and a transport_stream_id field. However, depending upon the embodiment of the present invention, it may be assumed that each of the 3 fields exists regardless of the FIC_seg_number field.

The current_next_indicator field is a 1-bit field. The current_next_indicator field acts as an indicator identifying whether the corresponding FIC data carry MH ensemble configuration information of an MH frame including the current FIC segment, or whether the corresponding FIC data carry MH ensemble configuration information of a next MH frame.

The ESG_version field is a 5-bit field indicating ESG version information. Herein, by providing version information on the service guide providing channel of the corresponding ESG, the ESG_version field enables the receiving system to notify whether or not the corresponding ESG has been updated.

Finally, the transport_stream_id field is a 16-bit field acting as a unique identifier of a broadcast stream through which the corresponding FIC segment is being transmitted.

A second region of the FIC segment payload corresponds to an ensemble loop region, which includes an ensemble_id field, an SI_version field, and a num_channel field.

More specifically, the ensemble_id field is an 8-bit field indicating identifiers of an MH ensemble through which MH services are transmitted. The MH services will be described in more detail in a later process. Herein, the ensemble_id field binds the MH services and the MH ensemble.

The SI_version field is a 4-bit field indicating version information of SI data included in the corresponding ensemble, which is being transmitted within the RS frame.

Finally, the num_channel field is an 8-bit field indicating the number of virtual channel being transmitted via the corresponding ensemble.

A third region of the FIC segment payload a channel loop region, which includes a channel_type field, a channel_activity field, a CA_indicator field, a stand_alone_service_indicator field, a major_channel_num field, and a minor_channel_num field.

The channel_type field is a 5-bit field indicating a service type of the corresponding virtual channel. For example, the channel_type field may indicates an audio/video channel, an audio/video and data channel, an audio-only channel, a data-only channel, a file download channel, an ESG delivery channel, a notification channel, and so on.

The channel_activity field is a 2-bit field indicating activity information of the corresponding virtual channel. More specifically, the channel_activity field may indicate whether the current virtual channel is providing the current service.

The CA_indicator field is a 1-bit field indicating whether or not a conditional access (CA) is applied to the current virtual channel.

The stand_alone_service_indicator field is also a 1-bit field, which indicates whether the service of the corresponding virtual channel corresponds to a stand alone service.

The major_channel_num field is an 8-bit field indicating a major channel number of the corresponding virtual channel.

Finally, the minor_channel_num field is also an 8-bit field indicating a minor channel number of the corresponding virtual channel.

Service Table Map

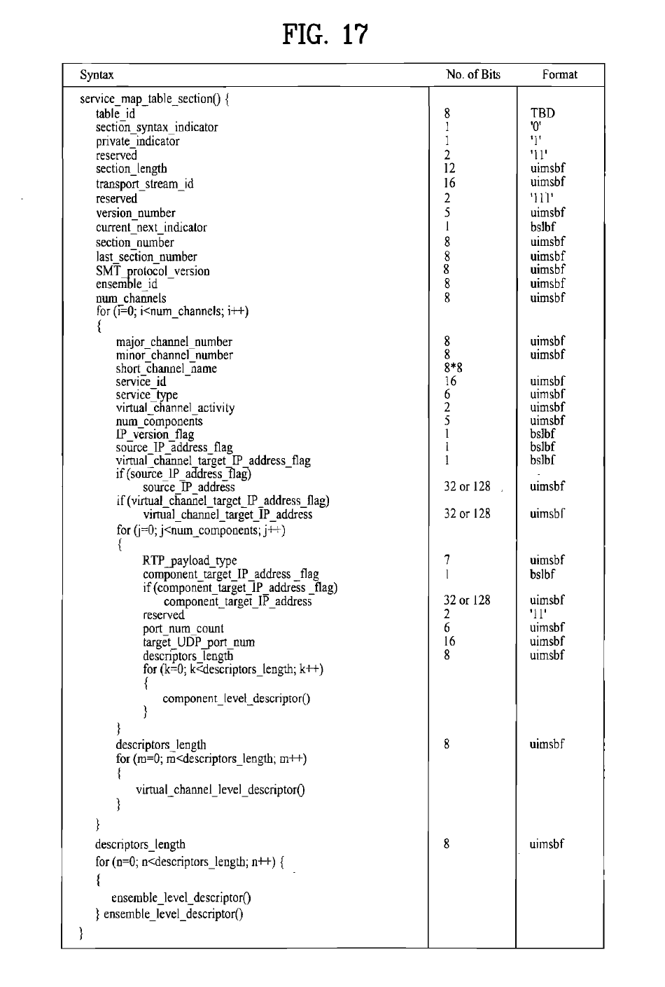

FIG. 17 illustrates an exemplary bit stream syntax structure of a service map table (hereinafter referred to as “SMT”) according to the present invention.

According to the embodiment of the present invention, the SMT is configured in an MPEG-2 private section format. However, this will not limit the scope and spirit of the present invention. The SMT according to the embodiment of the present invention includes description information for each virtual channel within a single MH ensemble. And, additional information may further be included in each descriptor area.

Herein, the SMT according to the embodiment of the present invention includes at least one field and is transmitted from the transmitting system to the receiving system.

As described in FIG. 3, the SMT section may be transmitted by being included in the MH TP within the RS frame. In this case, each of the RS frame decoders 170 and 180, shown in FIG. 1, decodes the inputted RS frame, respectively. Then, each of the decoded RS frames is outputted to the respective RS frame handler 211 and 212. Thereafter, each RS frame handler 211 and 212 identifies the inputted RS frame by row units, so as to create an MH TP, thereby outputting the created MH TP to the MH TP handler 213.

When it is determined that the corresponding MH TP includes an SMT section based upon the header in each of the inputted MH TP, the MH TP handler 213 parses the corresponding SMT section, so as to output the SI data within the parsed SMT section to the physical adaptation control signal handler 216. However, this is limited to when the SMT is not encapsulated to IP datagrams.

Meanwhile, when the SMT is encapsulated to IP datagrams, and when it is determined that the corresponding MH TP includes an SMT section based upon the header in each of the inputted MH TP, the MH TP handler 213 outputs the SMT section to the IP network stack 220. Accordingly, the IP network stack 220 performs IP and UDP processes on the inputted SMT section and, then, outputs the processed SMT section to the SI handler 240. The SI handler 240 parses the inputted SMT section and controls the system so that the parsed SI data can be stored in the storage unit 290.

The following corresponds to example of the fields that may be transmitted through the SMT.

A table_id field corresponds to an 8-bit unsigned integer number, which indicates the type of table section. The table_id field allows the corresponding table to be defined as the service map table (SMT).

An ensemble_id field is an 8-bit unsigned integer field, which corresponds to an ID value associated to the corresponding MH ensemble. Herein, the ensemble_id field may be assigned with a value ranging from range ‘0x00 ’ to ‘0x3F’. It is preferable that the value of the ensemble_id field is derived from the parade_id of the TPC data, which is carried from the baseband processor of MH physical layer subsystem. When the corresponding MH ensemble is transmitted through (or carried over) the primary RS frame, a value of ‘0 ’ may be used for the most significant bit (MSB), and the remaining 7 bits are used as the parade_id value of the associated MH parade (i.e., for the least significant 7 bits). Alternatively, when the corresponding MH ensemble is transmitted through (or carried over) the secondary RS frame, a value of ‘1 ’ may be used for the most significant bit (MSB).

A num_channels field is an 8-bit field, which specifies the number of virtual channels in the corresponding SMT section.

Meanwhile, the SMT according to the embodiment of the present invention provides information on a plurality of virtual channels using the ‘for’ loop statement.

A major_channel_num field corresponds to an 8-bit field, which represents the major channel number associated with the corresponding virtual channel. Herein, the major_channel_num field may be assigned with a value ranging from ‘0x00 ’ to ‘0xFF’.

A minor_channel_num field corresponds to an 8-bit field, which represents the minor channel number associated with the corresponding virtual channel. Herein, the minor_channel_num field may be assigned with a value ranging from ‘0x00 ’ to ‘0xFF’.

A short_channel_name field indicates the short name of the virtual channel. The service_id field is a 16-bit unsigned integer number (or value), which identifies the virtual channel service.

A service_type field is a 6-bit enumerated type field, which designates the type of service carried in the corresponding virtual channel as defined in Table 2 below.

TABLE 2

| | |
|---|---|
| 0x00 | [Reserved] |
| 0x01 | MH_digital_television field: the virtual channel |
| | carries television programming (audio, video |
| | and optional associated data) conforming to |
| | ATSC standards. |
| 0x02 | MH_audio field: the virtual channel carries |
| | audio programming (audio service and optional |
| | associated data) conforming to ATSC standards. |
| 0x03 | MH_data_only_service field: the virtual channel |
| | carries a data service conforming to ATSC |
| | standards, |
| | but no video or audio component. |
| 0x04 to | [Reserved for future ATSC usage] |
| 0xFF | |

A virtual_channel_activity field is a 2-bit enumerated field identifying the activity status of the corresponding virtual channel. When the most significant bit (MSB) of the virtual_channel_activity field is ‘1 ’, the virtual channel is active, and when the most significant bit (MSB) of the virtual_channel_activity field is ‘0 ’, the virtual channel is inactive. Also, when the least significant bit (LSB) of the virtual_channel_activity field is ‘1 ’, the virtual channel is hidden (when set to 1), and when the least significant bit (LSB) of the virtual_channel_activity field is ‘0 ’, the virtual channel is not hidden.

A num_components field is a 5-bit field, which specifies the number of IP stream components in the corresponding virtual channel.

An IP_version_flag field corresponds to a 1-bit indicator. More specifically, when the value of the IP_version_flag field is set to ‘1 ’, this indicates that a source_IP_address field, a virtual_channel_target_IP address field, and a component_target_IP_address field are IPv6 addresses. Alternatively, when the value of the IP_version_flag field is set to ‘0 ’, this indicates that the source_IP_address field, the virtual_channel_target_IP_address field, and the component_target_IP_address field are IPv4.

A source_IP_address_flag field is a 1-bit Boolean flag, which indicates, when set, that a source_IP_address of the corresponding virtual channel exist for a specific multicast source.

A virtual_channel_target_IP_address_flag field is a 1-bit Boolean flag, which indicates, when set, that the corresponding IP stream component is delivered through IP datagrams with target IP addresses different from the virtual_channel_target_IP_address. Therefore, when the flag is set, the receiving system (or receiver) uses the component_target_IP_address as the target_IP_address in order to access the corresponding IP stream component. Accordingly, the receiving system (or receiver) may ignore the virtual_channel_target_IP_address field included in the num_channels loop.

The source_IP_address field corresponds to a 32-bit or 128-bit field. Herein, the source_IP_address field will be significant (or present), when the value of the source_IP_address_flag field is set to ‘1 ’. However, when the value of the source_IP_address_flag field is set to ‘0 ’, the source_IP_address field will become insignificant (or absent). More specifically, when the source_IP_address_flag field value is set to ‘1 ’, and when the IP_version_flag field value is set to ‘0 ’, the source_IP_address field indicates a 32-bit IPv4 address, which shows the source of the corresponding virtual channel. Alternatively, when the IP_version_flag field value is set to ‘1 ’, the source_IP_address field indicates a 128-bit IPv6 address, which shows the source of the corresponding virtual channel.

The virtual_channel_target_IP_address field also corresponds to a 32-bit or 128-bit field. Herein, the virtual_channel_target_IP_address field will be significant (or present), when the value of the virtual_channel_target_IP_address_flag field is set to ‘1’. However, when the value of the virtual_channel_target_IP_address_flag field is set to ‘0 ’, the virtual_channel_target_IP_address field will become insignificant (or absent). More specifically, when the virtual_channel_target_IP_address_flag field value is set to ‘1 ’, and when the IP_version_flag field value is set to ‘0 ’, the virtual_channel_target_IP_address field indicates a 32-bit target IPv4 address associated to the corresponding virtual channel. Alternatively, when the virtual_channel_target_IP_address_flag field value is set to ‘1 ’, and when the IP_version_flag field value is set to ‘1 ’, the virtual_channel_target_IP_address field indicates a 64-bit target IPv6 address associated to the corresponding virtual channel. If the virtual_channel_target_IP_address field is insignificant (or absent), the component_target_IP_address field within the num channels loop should become significant (or present). And, in order to enable the receiving system to access the IP stream component, the component_target_IP_address field should be used.

Meanwhile, the SMT according to the embodiment of the present invention uses a ‘for’ loop statement in order to provide information on a plurality of components.

Herein, an RTP_payload_type field, which is assigned with 7 bits, identifies the encoding format of the component based upon Table 3 shown below. When the IP stream component is not encapsulated to RTP, the RTP_payload_type field shall be ignored (or deprecated).

Table 3 below shows an example of the RTP_payload_type.

TABLE 3

| RTP_payload_type | Meaning |
|---|---|
| 35 | AVC video |
| 36 | MH audio |
| 37 to 72 | [Reserved for future ATSC use] |

A component_target_IP_address_flag field is a 1-bit Boolean flag, which indicates, when set, that the corresponding IP stream component is delivered through IP datagrams with target IP addresses different from the virtual_channel_target_IP_address. Furthermore, when the component_target_IP_address_flag is set, the receiving system (or receiver) uses the component_target_IP_address field as the target IP address for accessing the corresponding IP stream component. Accordingly, the receiving system (or receiver) will ignore the virtual_channel_target_IP_address field included in the num_channels loop.

The component_target_IP_address field corresponds to a 32-bit or 128-bit field. Herein, when the value of the IP_version_flag field is set to ‘0 ’, the component_target_IP_address field indicates a 32-bit target IPv4 address associated to the corresponding IP stream component. And, when the value of the IP_version_flag field is set to ‘1 ’, the component_target_IP_address field indicates a 128-bit target IPv6 address associated to the corresponding IP stream component.

A port_num_count field is a 6-bit field, which indicates the number of UDP ports associated with the corresponding IP stream component. A target_UDP_port_number value starts from the target_UDP_port_num field value and increases (or is incremented) by 1. For the RTP stream, the target UDP port number should start from the target_UDP_port_num field value and shall increase (or be incremented) by 2. This is to incorporate RTCP streams associated with the RTP streams.

A target_UDP_port_num field is a 16-bit unsigned integer field, which represents the target_UDP_port_number for the corresponding IP stream component. When used for RTP streams, the value of the target_UDP_port_num field shall correspond to an even number. And, the next higher value shall represent the target UDP port number of the associated RTCP stream.

A component_level_descriptor( ) represents zero or more descriptors providing additional information on the corresponding IP stream component.

A virtual_channel_level_descriptor( ) represents zero or more descriptors providing additional information for the corresponding virtual channel.

An ensemble_level_descriptor( ) represents zero or more descriptors providing additional information for the MH ensemble, which is described by the corresponding SMT.

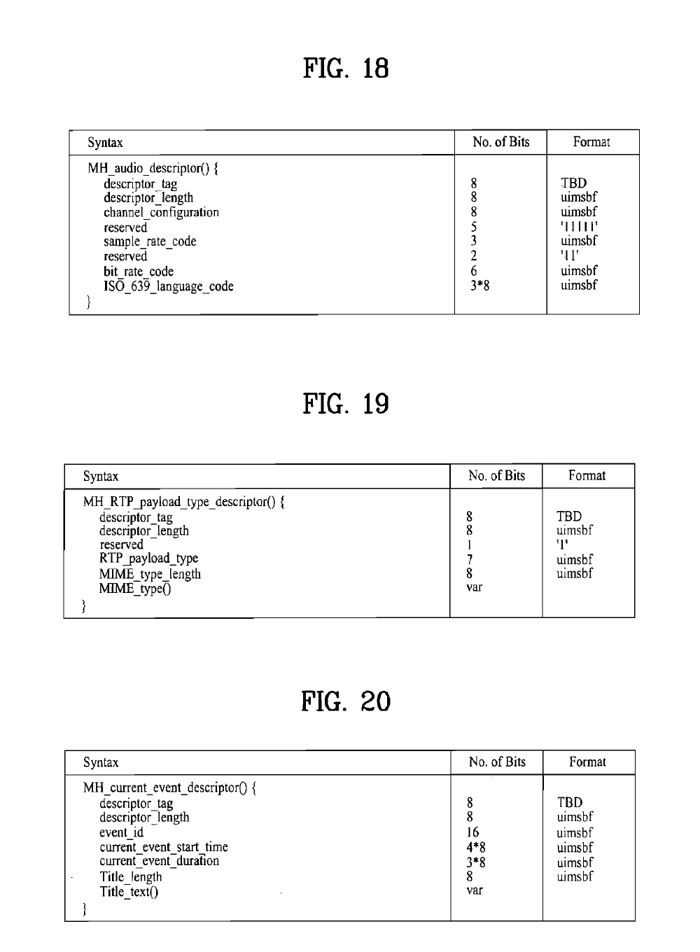

FIG. 18 illustrates an exemplary bit stream syntax structure of an MH audio descriptor according to the present invention.

When at least one audio service is present as a component of the current event, the MH_audio_descriptor( ) shall be used as a component_level_descriptor of the SMT. The MH_audio_descriptor( ) may be capable of informing the system of the audio language type and stereo mode status. If there is no audio service associated with the current event, then it is preferable that the MH_audio_descriptor( ) is considered to be insignificant (or absent) for the current event.

Each field shown in the bit stream syntax of FIG. 18 will now be described in detail.

A descriptor_tag field is an 8-bit unsigned integer having a TBD value, which indicates that the corresponding descriptor is the MH_audio_descriptor( ).

A descriptor_length field is also an 8-bit unsigned integer, which indicates the length (in bytes) of the portion immediately following the descriptor_length field up to the end of the MH_audio_descriptor( ).

A channel_configuration field corresponds to an 8-bit field indicating the number and configuration of audio channels. The values ranging from ‘1 ’ to ‘6 ’ respectively indicate the number and configuration of audio channels as given for “Default bit stream index number” in Table 42 of ISO/IEC 13818-7:2006. All other values indicate that the number and configuration of audio channels are undefined.

A sample_rate_code field is a 3-bit field, which indicates the sample rate of the encoded audio data. Herein, the indication may correspond to one specific sample rate, or may correspond to a set of values that include the sample rate of the encoded audio data as defined in Table A3.3 of ATSC A/52B.

A bit_rate_code field corresponds to a 6-bit field. Herein, among the 6 bits, the lower 5 bits indicate a nominal bit rate. More specifically, when the most significant bit (MSB) is ‘0 ’, the corresponding bit rate is exact. On the other hand, when the most significant bit (MSB) is ‘0 ’, the bit rate corresponds to an upper limit as defined in Table A3.4 of ATSC A/53B.

An ISO_{—}639_language_code field is a 24-bit (i.e., 3-byte) field indicating the language used for the audio stream component, in conformance with ISO 639.2/B [x]. When a specific language is not present in the corresponding audio stream component, the value of each byte will be set to ‘0x00 ’.

FIG. 19 illustrates an exemplary bit stream syntax structure of an MH RTP payload type descriptor according to the present invention.

The MH_RTP_payload_type descriptor( ) specifies the RTP payload type. Yet, the MH_RTP_payload_type descriptor( ) exists only when the dynamic value of the RTP_payload_type field within the num_components loop of the SMT is in the range of ‘96 ’ to ‘127 ’. The MH_RTP_payload_type descriptor( ) is used as a component_level_descriptor of the SMT.

The MH_RTP_payload_type descriptor translates (or matches) a dynamic RTP_payload_type field value into (or with) a MIME type. Accordingly, the receiving system (or receiver) may collect (or gather) the encoding format of the IP stream component, which is encapsulated in RTP.

The fields included in the MH_RTP_payload_type descriptor( ) will now be described in detail.

A descriptor_tag field corresponds to an 8-bit unsigned integer having the value TBD, which identifies the current descriptor as the MH_RTP_payload_type descriptor( ).

A descriptor_length field also corresponds to an 8-bit unsigned integer, which indicates the length (in bytes) of the portion immediately following the descriptor_length field up to the end of the MH_RTP_payload_type descriptor( ).

An RTP_payload_type field corresponds to a 7-bit field, which identifies the encoding format of the IP stream component. Herein, the dynamic value of the RTP_payload_type field is in the range of ‘96 ’ to ‘127’.

A MIME_type_length field specifies the length (in bytes) of a MIME_type_field.

The MIME_type field indicates the MIME type corresponding to the encoding format of the IP stream component, which is described by the MH_RTP_payload_type descriptor( ).

FIG. 20 illustrates an exemplary bit stream syntax structure of an MH current event descriptor according to the present invention.

The MH_current_event_descriptor( ) shall be used as the virtual_channel_level_descriptor( ) within the SMT. Herein, the MH_current_event_descriptor( ) provides basic information on the current event (e.g., the start time, duration, and title of the current event, etc.), which is transmitted via the respective virtual channel.

The fields included in the MH_current_event_descriptor( ) will now be described in detail.

A descriptor_tag field corresponds to an 8-bit unsigned integer having the value TBD, which identifies the current descriptor as the MH_current_event_descriptor( ).

A descriptor_length field also corresponds to an 8-bit unsigned integer, which indicates the length (in bytes) of the portion immediately following the descriptor_length field up to the end of the MH_current_event_descriptor( ).

A current_event_start_time field corresponds to a 32-bit unsigned integer quantity. The current_event_start_time field represents the start time of the current event and, more specifically, as the number of GPS seconds since 00:00:00 UTC, Jan. 6, 1980.

A current_event_duration field corresponds to a 24-bit field. Herein, the current_event duration field indicates the duration of the current event in hours, minutes, and seconds (wherein the format is in 6 digits, 4-bit BCD=24 bits).

A title_length field specifies the length (in bytes) of a title_text field. Herein, the value ‘0 ’ indicates that there are no titles existing for the corresponding event.

The title_text field indicates the title of the corresponding event in event title in the format of a multiple string structure as defined in ATSC A/65C [x].

FIG. 21 illustrates an exemplary bit stream syntax structure of an MH next event descriptor according to the present invention.

The optional MH_next_event_descriptor( ) shall be used as the virtual_channel_level_descriptor( ) within the SMT. Herein, the MH_next_event_descriptor( ) provides basic information on the next event (e.g., the start time, duration, and title of the next event, etc.), which is transmitted via the respective virtual channel.

The fields included in the MH_next_event_descriptor( ) will now be described in detail.

A descriptor_tag field corresponds to an 8-bit unsigned integer having the value TBD, which identifies the current descriptor as the MH_next_event_descriptor( ).

A descriptor_length field also corresponds to an 8-bit unsigned integer, which indicates the length (in bytes) of the portion immediately following the descriptor_length field up to the end of the MH_next_event_descriptor( ).

A next_event_start_time field corresponds to a 32-bit unsigned integer quantity. The next_event_start_time field represents the start time of the next event and, more specifically, as the number of GPS seconds since 00:00:00 UTC, Jan. 6, 1980.

A next_event_duration field corresponds to a 24-bit field. Herein, the next_event_duration field indicates the duration of the next event in hours, minutes, and seconds (wherein the format is in 6 digits, 4-bit BCD=24 bits).

A title_length field specifies the length (in bytes) of a title_text field. Herein, the value ‘0 ’ indicates that there are no titles existing for the corresponding event.

The title_text field indicates the title of the corresponding event in event title in the format of a multiple string structure as defined in ATSC A/65C [x].

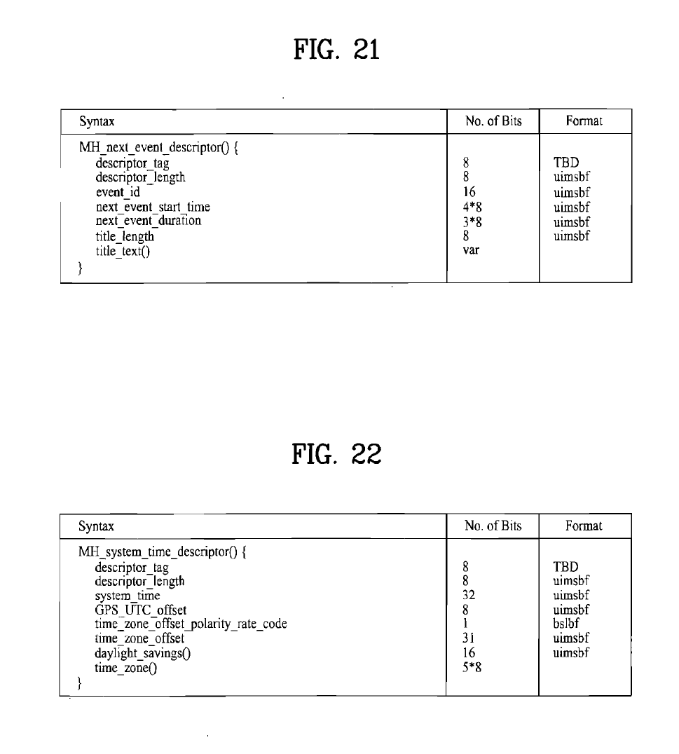

FIG. 22 illustrates an exemplary bit stream syntax structure of an MH system time descriptor according to the present invention.

The MH_system_time_descriptor( ) shall be used as the ensemble_level_descriptor( ) within the SMT. Herein, the MH_system_time_descriptor( ) provides information on current time and date. The MH_system_time_descriptor( ) also provides information on the time zone in which the transmitting system (or transmitter) transmitting the corresponding broadcast stream is located, while taking into consideration the mobile/portable characteristics of the MH service data.

The fields included in the MH_system_time_descriptor( ) will now be described in detail.

A descriptor_tag field corresponds to an 8-bit unsigned integer having the value TBD, which identifies the current descriptor as the MH_system_time_descriptor( ).

A descriptor_length field also corresponds to an 8-bit unsigned integer, which indicates the length (in bytes) of the portion immediately following the descriptor_length field up to the end of the MH_system_time_descriptor( ).

A system_time field corresponds to a 32-bit unsigned integer quantity. The system_time field represents the current system time and, more specifically, as the number of GPS seconds since 00:00:00 UTC, Jan. 6, 1980.

A GPS_UTC_offset field corresponds to an 8-bit unsigned integer, which defines the current offset in whole seconds between GPS and UTC time standards. In order to convert GPS time to UTC time, the GPS_UTC offset is subtracted from GPS time. Whenever the International Bureau of Weights and Measures decides that the current offset is too far in error, an additional leap second may be added (or subtracted). Accordingly, the GPS_UTC offset field value will reflect the change.

A time_zone_offset_polarity field is a 1-bit field, which indicates whether the time of the time zone, in which the broadcast station is located, exceeds (or leads or is faster) or falls behind (or lags or is slower) than the UTC time. When the value of the time_zone_offset_polarity field is equal to ‘0 ’, this indicates that the time on the current time zone exceeds the UTC time. Therefore, a time_zone_offset field value is added to the UTC time value. Conversely, when the value of the time_zone_offset_polarity field is equal to ‘1 ’, this indicates that the time on the current time zone falls behind the UTC time. Therefore, the time_zone_offset field value is subtracted from the UTC time value.

The time_zone_offset field is a 31-bit unsigned integer quantity. More specifically, the time_zone_offset field represents, in GPS seconds, the time offset of the time zone in which the broadcast station is located, when compared to the UTC time.

A daylight_savings field corresponds to a 16-bit field providing information on the Summer Time (i.e., the Daylight Savings Time).

A time_zone field corresponds to a (5×8)-bit field indicating the time zone, in which the transmitting system (or transmitter) transmitting the corresponding broadcast stream is located.

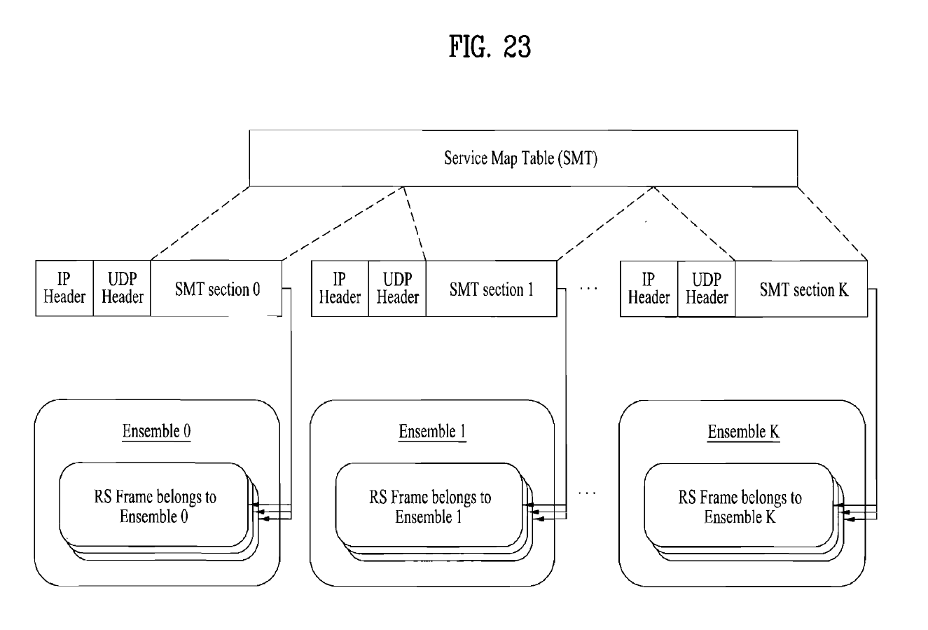

FIG. 23 illustrates segmentation and encapsulation processes of a service map table (SMT) according to the present invention.

According to the present invention, the SMT is encapsulated to UDP, while including a target IP address and a target_UDP_port_number within the IP datagram. More specifically, the SMT is first segmented into a predetermined number of sections, then encapsulated to a UDP header, and finally encapsulated to an IP header.

In addition, the SMT section provides signaling information on all virtual channel included in the MH ensemble including the corresponding SMT section. At least one SMT section describing the MH ensemble is included in each RS frame included in the corresponding MH ensemble. Finally, each SMT section is identified by an ensemble_id included in each section.

According to the embodiment of the present invention, by informing the receiving system of the target IP address and target UDP port number, the corresponding data (i.e., target IP address and target UDP port number) may be parsed without having the receiving system to request for other additional information.

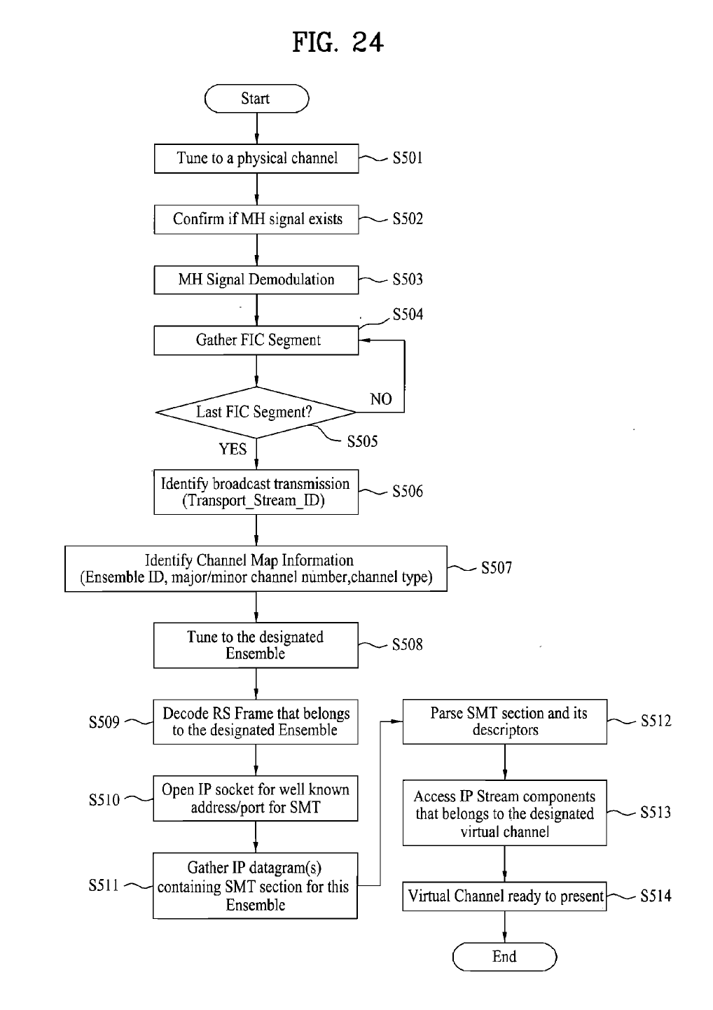

FIG. 24 illustrates a flow chart for accessing a virtual channel using FIC and SMT according to the present invention.

More specifically, a physical channel is tuned (S501). And, when it is determined that an MH signal exists in the tuned physical channel (S502), the corresponding MH signal is demodulated (S503). Additionally, FIC segments are grouped from the demodulated MH signal in sub-frame units (S504 and S505).

According to the embodiment of the present invention, an FIC segment is inserted in a data group, so as to be transmitted. More specifically, the FIC segment corresponding to each data group described service information on the MH ensemble to which the corresponding data group belongs. When the FIC segments are grouped in sub-frame units and, then, deinterleaved, all service information on the physical channel through which the corresponding FIC segment is transmitted may be acquired. Therefore, after the tuning process, the receiving system may acquire channel information on the corresponding physical channel during a sub-frame period. Once the FIC segments are grouped, in 5504 and 5505, a broadcast stream through which the corresponding FIC segment is being transmitted is identified (S506). For example, the broadcast stream may be identified by parsing the transport_stream_id field of the FIC body, which is configured by grouping the FIC segments.

Furthermore, an ensemble identifier, a major channel number, a minor channel number, channel type information, and so on, are extracted from the FIC body (S507). And, by using the extracted ensemble information, only the slots corresponding to the designated ensemble are acquired by using the time-slicing method, so as to configure an ensemble (S508).

Subsequently, the RS frame corresponding to the designated ensemble is decoded (S509), and an IP socket is opened for SMT reception (S510).

According to the example given in the embodiment of the present invention, the SMT is encapsulated to UDP, while including a target IP address and a target UDP port number within the IP datagram. More specifically, the SMT is first segmented into a predetermined number of sections, then encapsulated to a UDP header, and finally encapsulated to an IP header. According to the embodiment of the present invention, by informing the receiving system of the target IP address and target UDP port number, the receiving system parses the SMT sections and the descriptors of each SMT section without requesting for other additional information (S511).

The SMT section provides signaling information on all virtual channel included in the MH ensemble including the corresponding SMT section. At least one SMT section describing the MH ensemble is included in each RS frame included in the corresponding MH ensemble. Also, each SMT section is identified by an ensemble_id included in each section.

Furthermore each SMT provides IP access information on each virtual channel subordinate to the corresponding MH ensemble including each SMT. Finally, the SMT provides IP stream component level information required for the servicing of the corresponding virtual channel.

Therefore, by using the information parsed from the SMT, the IP stream component belonging to the virtual channel requested for reception may be accessed (S513). Accordingly, the service associated with the corresponding virtual channel is provided to the user (S514).

Meanwhile, the present invention is intended to transmit and receive notification information as well as mobile broadcast service.

The notification information is transmitted to the receiving system through a notification message provided from the network.

According to the embodiment of the present invention, the notification messages are transmitted through RTP or FLUTE protocol. For example, the RTP protocol is applied to notification messages having time restriction, and the FLUTE protocol is applied to notification messages having no time restriction.

FIG. 25 illustrates an example of a protocol stack for transmitting and receiving notification messages based on IP.

In FIG. 25, the notification messages are packetized in the IP layer accordance with an RTP mode or a FLUTE mode. The RTP packets or FLUTE packets are transmitted to the UDP/IP header by encapsulation.

Information transmitted through the notification messages may be associated with the network, IP platform, or service described in ESG.

The notification messages according to the present invention can be divided into default notification messages and user-selected messages.

The receiving system can automatically access the default notification messages. Namely, the notification messages are automatically received to all terminals within a broadcast network and then processed therein without a special selection of a user.

The default messages can be divided into network default notification (NDN) messages, platform default notification (PDN) messages, and ESG default notification (EDN) messages in accordance with notification contents.

The NDN messages means messages associated with MH network. For example, the NDN messages are associated with emergency alarm, broadcasting cancellation, and variation of network connection parameter values. In the present invention, it is intended that the receiving system connected with the corresponding network can receive the NDN messages without a selection procedure of a user.

The PDN messages mean messages associated with a specific IP platform. For example, the PDN messages are associated with variation of platform establishment. In the present invention, it is intended that the receiving system belonging to the corresponding IP platform can receive the PDN messages without a selection procedure of a user.

The EDN messages mean messages associated with a service described in a specific ESG. For example, the EDN messages are associated with an ESG provider or a service described in the ESG. In the present invention, it is intended that the receiving system receiving ESG of a specific ESG provider can receive the PDN messages without a selection procedure of a user.

The user-selected notification messages mean messages associated with a service found in the ESG. In the present invention, notification messages received and processed only if the user selects the service transferred through the ESG and notification components will be referred to as user-selected notification messages.

The user-selected notification messages can be divided into service related notification (SRN) messages and notification service messages.

The SRN messages are notification messages associated with a specific service described in the ESG. According to the embodiment of the present invention, these notification messages are transmitted to one of a service session. If the SRN messages should be synchronized with A/V (audio/video) services, the RTP protocol is used together with the FLUTE protocol to provide synchronization information.

The notification service messages mean A/V services provided through the notification message. For example, news can be transmitted using the notification service messages.

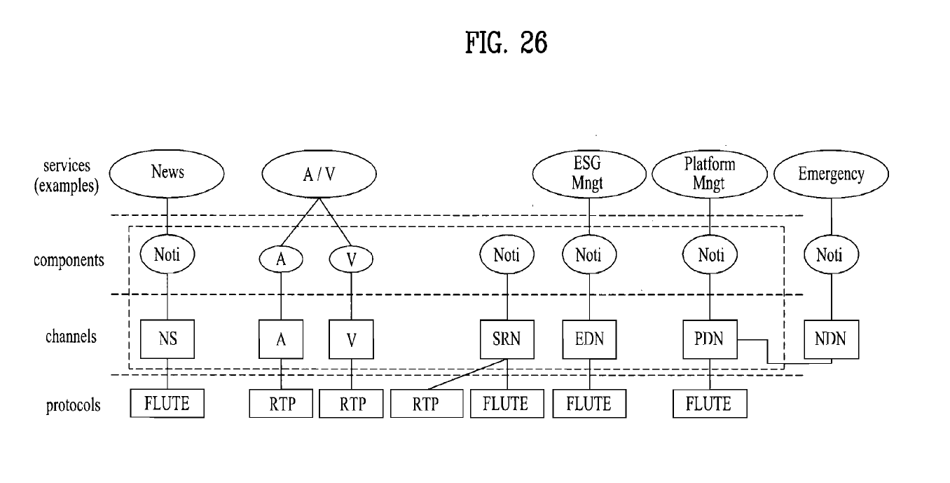

FIG. 26 illustrates an example of a notification framework for transmitting/receiving the default notification messages and the user-selected notification messages.

In other words, a notification channel and protocol are selected in accordance with notification contents of each notification component through the default notification messages and the user-selected notification messages.

For example, a notification component corresponding to a notification message such as news service is transmitted in a FLUTE mode through a notification service (NS) channel. At this time, the default notification services are provided through a default notification channel. The default notification channel has a value previously agreed between the transmitting/receiving systems. Accordingly, the receiving system can receive and process the notification messages transmitted to the default notification channel without separate access information. According to the embodiment of the present invention, the user-selected notification service is received through the ESG. This is because that channels associated with the broadcast service are described in the ESG.

As illustrated in FIG. 26, the notification messages can be transmitted at different formats in accordance with their sizes, components and channels. For example, the FLUTE protocol is applied to the notification messages having no time restriction, and the RTP protocol is applied to the notification messages having time restriction.

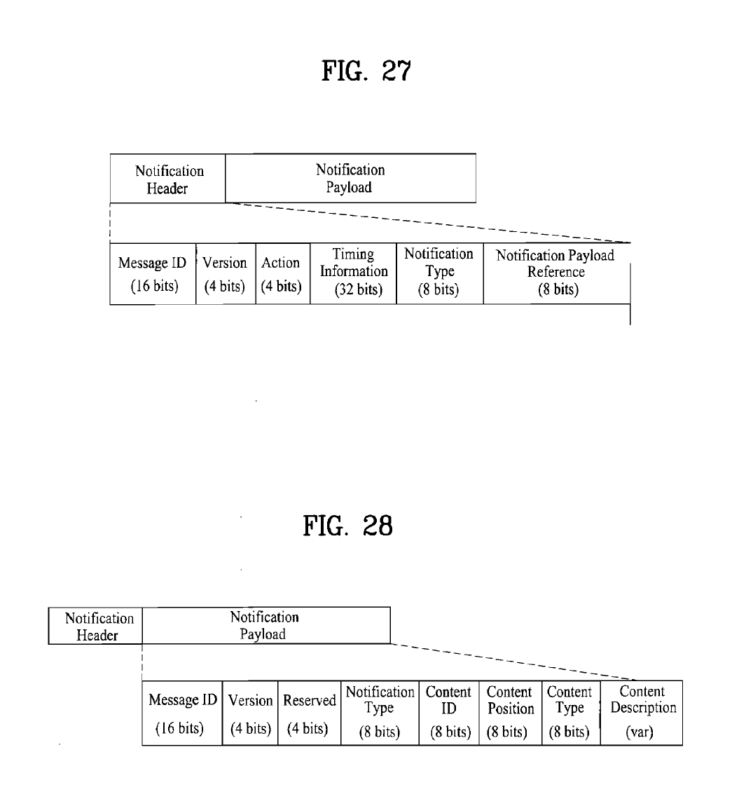

These notification messages include a notification header and a notification payload as illustrated in FIG. 27. Actual notification contents are received through the notification payload, and the notification header includes information associated with the notification messages received to the notification payload.

At this time, according to the embodiment of the present invention, if the notification messages are transmitted through the FLUTE protocol, data of the notification header of the notification messages are transmitted through a file delivery table (FDT), and data of the notification payload are transmitted through the transport object part of the FULTE protocol. Also, according to the embodiment of the present invention, the notification messages are transmitted in a XML document type.

Meanwhile, according to the embodiment of the present invention, if the notification messages are transmitted through the RTP protocol, data of the notification header of the notification messages are transmitted through the RTP header, and data of the notification payload are transmitted through the RTP payload part.

For example, the notification header can have a size of 9 bytes, and can include a message ID field, a version field, an action field, a time information field, a notification type field, and a notification payload reference field, as illustrated in FIG. 27. The size of the notification header is only exemplary, and since the size of the notification header can easily be modified by a system designer, the present invention is not limited to the above example.

The message ID field (16 bits) represents a unique identification value that can identify the notification messages received to the corresponding notification payload.

The version field (4 bits) represents version of the notification messages received to the corresponding notification payload.

The action field (4 bits) describes action performed through the notification messages. In the present invention, three types of actions are defined.

For example, if the action field has a value of 0, it indicates launch. If the action field has a value of 1, it indicates active. If the action field has a value of 2, it indicates remove.

The time information field (32 bits) represents time information of each action indicated by the action field. For example, if the action field has a value of 0, the time information field represents a display presentation time. If the action field has a value of 1, the notification messages are activated so that the time information field represents relative time until the notification messages are automatically canceled. If the action field has a value of 2, the time information field represents a cancel time when the notification messages are automatically canceled from the screen.

The notification type field (8 bits) represents definition as to whether the receiving system which has received the notification messages will provide what service. For example, the notification type field can have a value of 0 to 255. A target-application service type for each value will be defined later.

The notification payload reference field (8 bits) represents URI value for the payload of the notification messages identified by the message ID. For example, if the notification messages are transmitted through the FLUTE protocol, the notification payload reference field represents URI value of the notification data transmitted to the FULTE object part.

FIG. 28 illustrates an example of a structure of a notification payload of the notification messages according to the present invention. The notification payload can include a message ID field, a version field, a notification type field, a content ID field, a content position field, a content type field, and a content description field.

The message ID field (16 bits) represents a unique identification value that can identify the notification messages received to the corresponding notification payload. Namely, since the notification header and the notification payload of the notification messages are transmitted by being divided into either FDT part and a transport object part or RTP header part and RTP payload part in accordance with a transport protocol, the receiving system configures corresponding notification messages using a message ID value of the notification header and a message ID value of the notification payload as link information.

The version field (4 bits) represents version of the notification messages received to the corresponding notification payload.

The notification type field (8 bits) represents definition as to whether the receiving system which has received the notification messages will provide what service.

The content ID field (8 bits) represents an identifier for identifying contents (i.e., notification contents) transmitted to the notification payload.

The content position field (8 bits) represents position information of each content if the notification content is transmitted by being divided into several contents. Namely, the content position field can represent position information in each file.

The content type field (8 bits) represents a type of the corresponding notification content. For example, the content type field represents whether the corresponding notification content is audio, video, text, or image.

The content description field describes textual description information of contents. Namely, the actual notification contents are transmitted through the content description field. The content description field has a variable length. In this case, the size of each field of the notification payload is exemplary.

As described above, in the present invention, if the notification messages are transmitted through the RTP protocol, data of the notification header of the notification messages are transmitted through the RTP header, and data of the notification payload are transmitted through the RTP payload part.

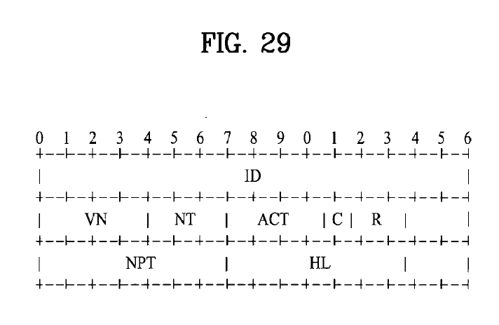

FIG. 29 illustrates an example of a structure of the RTP header of RTP packet, which transmits the notification messages. The RTP header can include an ID field, a version number (VN) field, a notification type (NT) field, an action type (ACT) field, a compression (C) field, a reserved (R) field, a notification payload type (NPT) field, and a header length (HL) field.

The ID field (16 bits) represents an identifier of the notification messages, and the VN field (4 bits) represents version of the notification messages. The NT field (4 bits) represents a notification type, and the ACT field (4 bits) represents an action type of the notification messages. The C field (1 bit) represents whether compression of the notification messages has been performed, and the R field (3 bits) represents a field which is not used. The NPT field (8 bits) represents notification payload reference. The HL field (8 bits) represents a length of the notification header.

The aforementioned notification messages are packetized in accordance with the RTP protocol or the FLUTE protocol. The notification messages are again packetized in accordance with the UDP/IP protocol and then transmitted by being included in the MH TP within the RS frames. At this time, the RS frames could be RS frames of ensemble which includes a default dedicated channel, or RS frames of ensemble which includes ESG channel. In this case, the RS frame decoders 170 and 180 of FIG. 1 decode the input RS frames and output the decoded RS frames to the corresponding frame handlers 211 and 212. Each of the RS frame handlers 211 and 212 configure MH TPs by dividing the input RS frames in a low unit and outputs the configured MH TPs to the MH TP handler 213.

If the MH TP handler 213 determines that the corresponding MH TP includes the notification messages, based on a header of each MH TP, the MH TP handler 213 outputs the corresponding MH TP to the IP network stack 220. Then, the IP network stack 220 performs IP, UDP decapsulation for the notification messages and then outputs the decapsulated notification messages to the file handler 250 if the decapsulated notification messages are file type. However, if the decapsulated notification messages are RTP type, the IP network stack 220 extracts the data of the notification header and the notification payload from the RTP header and the RTP payload to configure the notification messages. Then, the IP network stack 220 outputs the configured notification messages to the presentation controller 330 through the SI handler 240 and the storage 290.

The file handler 250 extracts the data of the notification header and the notification payload from the FDT and the transport object part to configure the notification messages. Then, the file handler 250 outputs the configured notification messages to the presentation controller 330 through the storage 290.

If the notification messages stored in the storage 29 are default notification messages, the presentation controller 330 automatically displays the corresponding notification contents on the screen through the display module 320. If the notification messages stored in the storage 29 are user-selected notification messages, the presentation controller 330 displays the corresponding notification contents on the screen through the display module 320 only if there is the user's selection.

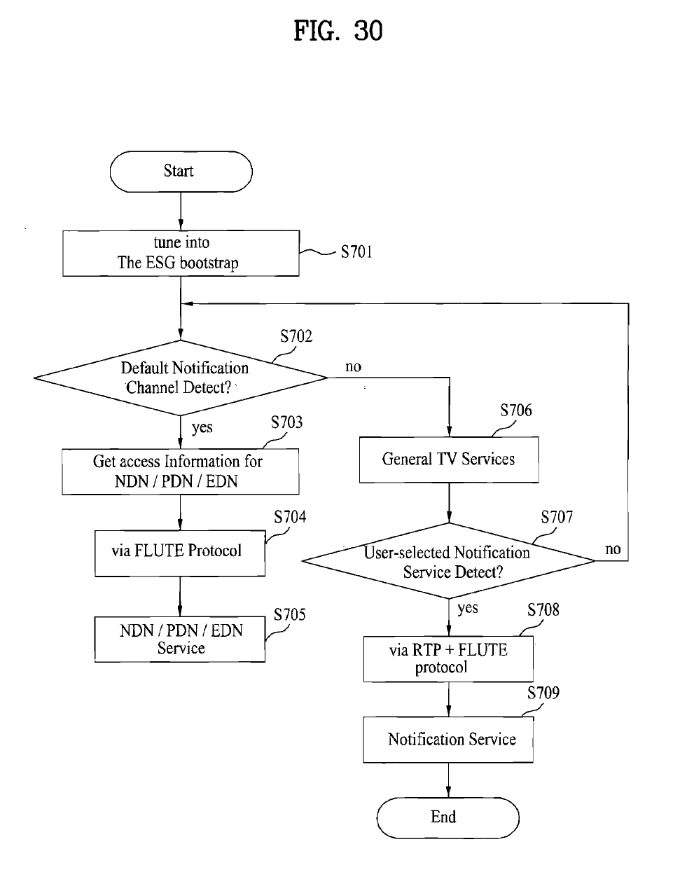

FIG. 30 is a flow chart illustrating an example of a method of receiving and serving the notification messages in accordance with the present invention.

In other words, if the receiving system is powered on, the receiving system is tuned into the ESG bootstrap (S701), and checks whether the default notification channel is detected (S702). At this time, since the default notification channel is previously agreed between the transmitting/receiving systems, the receiving system always opens a corresponding socket and receives the notification messages, which are transmitted to the default notification channel, without condition. In the step S702, if it is identified that the default notification channel has been detected, the receiving system collects access information for accessing the default notification messages (for example, NDN, PDN, and EDN) (S703). The access information can be acquired through the notification header, and the data of the notification header are received through the FDT of the FLUTE protocol or the RTP header of the RTP protocol.

At this time, the default notification messages are received through the FLUTE protocol (S704). The receiving system accesses the data of the notification payload received to the transport object part of the FLUTE protocol with reference to the acquired access information and then displays the corresponding notification contents of the accessed notification payload on the screen (S705).

Meanwhile, if the default notification channel is not detected in the step S702, the receiving system provides a general broadcast service (S706) and at the same time checks whether the user-selected notification service (NS) is detected (S707). Since the user-selected notification service is received through the RTP protocol and the FLUTE protocol, the receiving system receives the notification messages corresponding to the user-selected notification service to process both RTP and FLUTE (S708). The receiving system displays the notification service acquired from the corresponding notification messages on the screen (S709).

As described above, according to the present invention, the receiving system receives and processes the notification messages transmitted through the default notification channel or the ESG channel, so that the user can easily recognize emergency situation or modification in service contents.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

1-14. (canceled)

15. A method of processing broadcast data in a broadcast receiver, the method comprising:
receiving a broadcast signal comprising mobile service data, a signaling information table, regularly spaced known data sequences, fast information channel (FIC) data, and transmission parameter channel (TPC) data, wherein the mobile service data and the signaling information table are packaged into at least one of a plurality of Reed Solomon (RS) frames, wherein the FIC data comprises information for rapid mobile service acquisition, and wherein the TPC data comprises FIC version information for indicating an update of the FIC data and a parade identifier to identify a parade;
decoding the at least one of the plurality of RS frames from the received broadcast signal;
obtaining the signaling information table from the decoded at least one of the plurality of RS frames; and
obtaining an Internet protocol (IP) datagram of the mobile service data using the obtained signaling information table,
wherein the signaling information table is received according to at least one section, each of the at least one section comprising a section header and a section body, wherein the section header comprises an ensemble identifier to identify an ensemble and the section body includes access information of the mobile service data, and wherein the ensemble identifier comprises the parade identifier.

16. The method of claim 15, wherein the at least one of the plurality of RS frames belongs to a primary ensemble or a secondary ensemble.

17. The method of claim 16, wherein the primary ensemble is carried over primary RS frames and wherein the secondary ensemble is carried over secondary RS frames.

18. The method of claim 16, wherein the parade carries at least one of the primary ensemble and the secondary ensemble.

19. The method of claim 16, wherein the ensemble identifier is for the primary ensemble carried through the parade when a most significant bit (MSB) of the ensemble identifier is set to ‘0’.

20. The method of claim 16, wherein the ensemble identifier is for the secondary ensemble carried through the parade when a most significant bit (MSB) of the ensemble identifier is set to ‘1’.

21. The method of claim 16, wherein a least significant 7-bits of the ensemble identifier correspond to the parade identifier.

22. The method of claim 15, wherein at least two of the known data sequences are spaced 16 segments apart and have different lengths.

23. A broadcast receiver comprising:
a tuner for receiving a broadcast signal, the broadcast signal comprising mobile service data, a signaling information table, regularly spaced known data sequences, fast information channel (FIC) data, and transmission parameter channel (TPC) data, wherein the mobile service data and the signaling information table are packaged into at least one of a plurality of Reed Solomon (RS) frames, wherein the FIC data comprises information for rapid mobile service acquisition, and wherein the TPC data comprises FIC version information for indicating an update of the FIC data and a parade identifier to identify a parade;
a decoder for decoding the at least one of the plurality of RS frames from the received broadcast signal;
a first handler for obtaining the signaling information table from the decoded at least one of the plurality of RS frames; and
a second handler for obtaining an Internet protocol (IP) datagram of the mobile service data using the obtained signaling information table,
wherein the signaling information table is received according to at least one section, each of the at least one section comprising a section header and a section body, wherein the section header comprises an ensemble identifier to identify an ensemble and the section body includes access information of the mobile service data, and wherein the ensemble identifier comprises the parade identifier.

24. The broadcast receiver of claim 23, wherein the at least one of the RS frames belongs to a primary ensemble or a secondary ensemble.

25. The broadcast receiver of claim 24, wherein the primary ensemble is carried over primary RS frames and wherein the secondary ensemble is carried over secondary RS frames.

26. The broadcast receiver of claim 24, wherein the parade carries at least one of the primary ensemble and the secondary ensemble.

27. The broadcast receiver of claim 24, wherein the ensemble identifier is for the primary ensemble carried through the parade when a most significant bit (MSB) of the ensemble identifier is set to ‘0’.

28. The broadcast receiver of claim 24, wherein the ensemble identifier is for the secondary ensemble carried through the parade when a most significant bit (MSB) of the ensemble identifier is set to ‘1’.

29. The broadcast receiver of claim 24, wherein a least significant 7-bits of the ensemble identifier correspond to the parade identifier.

30. The broadcast receiver of claim 23, wherein at least two of the known data sequences are spaced 16 segments apart and have different lengths.

31. A method of processing broadcast data in a broadcast transmitter, the method comprising:
performing, by a Reed Solomon (RS) encoder, RS encoding and Cyclic Redundancy Check (CRC) encoding on mobile service data and a signaling information table comprising access information of the mobile service data, thereby packaging the mobile service data and the signaling information table into at least one of a plurality of RS frames;
mapping the at least one of the plurality of RS frames into a plurality of groups, wherein each of the plurality of groups comprises a portion of data included in a corresponding one of the plurality of RS frames, regularly spaced known data sequences, fast information channel (FIC) data, and transmission parameter channel (TPC) data, wherein the FIC data comprises information for rapid mobile service acquisition, and wherein the TPC data includes FIC version information for indicating an update of the FIC data and a parade identifier to identify a parade; and
transmitting a broadcast signal including the plurality of groups,
wherein the signaling information table is carried according to at least one section, each of the at least one section comprising a section header and a section body, wherein the section header comprises an ensemble identifier to identify an ensemble and the section body comprises access information of the mobile service data, and wherein the ensemble identifier comprises the parade identifier.

32. The method of claim 31, wherein the at least one of the plurality of RS frames belongs to a primary ensemble or a secondary ensemble.

33. The method of claim 32, wherein the primary ensemble is carried over primary RS frames and wherein the secondary ensemble is carried over secondary RS frames.

34. The method of claim 32, wherein the parade carries at least one of the primary ensemble and the secondary ensemble.

35. The method of claim 32, wherein the ensemble identifier is for the primary ensemble carried through the parade when a most significant bit (MSB) of the ensemble identifier is set to ‘0’.

36. The method of claim 32, wherein the ensemble identifier is for the secondary ensemble carried through the parade when a most significant bit (MSB) of the ensemble identifier is set to ‘1’.

37. The method of claim 32, wherein a least significant 7-bits of the ensemble identifier correspond to the parade identifier.

38. The method of claim 31, wherein at least two of the known data sequences are spaced 16 segments apart and have different lengths.

39. A broadcast transmitter comprising:
a Reed Solomon (RS) encoder for performing RS encoding and Cyclic Redundancy Check (CRC) encoding on mobile service data and a signaling information table that includes access information of the mobile service data, thereby packaging the mobile service data and the signaling information table into at least one of a plurality of RS frames;
a group formatting means for mapping the at least one of the plurality of RS frames into a plurality of groups, wherein each of the plurality of groups comprises a portion of data included in a corresponding one of the plurality of RS frames, regularly spaced known data sequences, fast information channel (FIC) data, and transmission parameter channel (TPC) data, wherein the FIC data comprises information for rapid mobile service acquisition, and wherein the TPC data includes FIC version information for indicating an update of the FIC data and a parade identifier to identify a parade; and
a transmitting means for transmitting a broadcast signal including the plurality of groups,
wherein the signaling information table is carried according to at least one section, each of the at least one section comprising a section header and a section body, wherein the section header comprises an ensemble identifier to identify an ensemble and the section body comprises access information of the mobile service data, and wherein the ensemble identifier comprises the parade identifier.

40. The broadcast transmitter of claim 39, wherein the at least one of the plurality of RS frames belongs to a primary ensemble or a secondary ensemble.

41. The broadcast transmitter of claim 40, wherein the primary ensemble is carried over primary RS frames and wherein the secondary ensemble is carried over secondary RS frames.

42. The broadcast transmitter of claim 40, wherein the parade carries at least one of the primary ensemble and the secondary ensemble.

43. The broadcast transmitter of claim 40, wherein the ensemble identifier is for the primary ensemble carried through the parade when a most significant bit (MSB) of the ensemble identifier is set to ‘0’.

44. The broadcast transmitter of claim 40, wherein the ensemble identifier is for the secondary ensemble carried through the parade when a most significant bit (MSB) of the ensemble identifier is set to ‘1’.

45. The broadcast transmitter of claim 40, wherein a least significant 7-bits of the ensemble identifier correspond to the parade identifier.

46. The broadcast transmitter of claim 39, wherein at least two of the known data sequences are spaced 16 segments apart and have different lengths.
